(19) United States
(12) Patent Application Publication
(10) Pub. No.: US 2024/0142877 A1
(43) Pub. Date: May 2, 2024

(54) EXPOSURE APPARATUS AND MEASUREMENT SYSTEM

(71) Applicant: NIKON CORPORATION, Tokyo (JP)

(72) Inventors: Masaki KATO, Yokohama-shi (JP); Yasushi MIZUNO, Saitama-shi (JP)

(73) Assignee: NIKON CORPORATION, Tokyo (JP)

(21) Appl. No.: 18/544,838

(22) Filed: Dec. 19, 2023

Related U.S. Application Data
(63) Continuation of application No. PCT/JP2022/027236, filed on Jul. 11, 2022.

(30) Foreign Application Priority Data
Jul. 12, 2021 (JP) 2021-115323

(51) Int. Cl. G03F 7/20; G03F 7/00

(52) U.S. Cl. CPC G03F 7/20; G03F 7/70258; G03F 7/70291; G03F 7/7085

(57) ABSTRACT

An exposure apparatus includes a substrate stage on which substrates are placed, and first projection modules each including a spatial light modulator, the first projection modules projecting wiring patterns each connecting semiconductor chips arranged on each of the substrates onto the substrates, wherein the first projection modules project the wiring patterns onto different substrates, substantially simultaneously.

### CROSS-REFERENCE TO RELATED APPLICATION

This application is based upon and claims the benefit of priority of the prior International Patent Application No. PCT/JP2022/027236, filed on Jul. 11, 2022, the entire contents of which are incorporated herein by reference.

### FIELD

The present disclosure relates to an exposure apparatus and a measurement system.

### BACKGROUND

In recent years, packages of semiconductor devices called FO-WLP (Fan Out Wafer Level Package) and FO-PLP (Fan Out Plate Level Package) have been known.

For example, in the manufacture of the FO-WLP, a plurality of semiconductor chips are arranged on a wafer-shaped support substrate and are fixed with a mold material such as a resin to form a pseudo wafer, and a rewiring layer for connecting pads of the semiconductor chips to each other is formed using an exposure apparatus (Patent Document 1: Japanese Patent Application Laid-Open No. 2018-081281).

### SUMMARY

It is desired to improve the throughput in the formation of the rewiring layers of the FO-WLP and the FO-PLP.

In one aspect of the present disclosure, there is provided an exposure apparatus including: a substrate stage on which substrates are placed; and first projection modules each including a spatial light modulator, the first projection modules projecting wiring patterns each connecting semiconductor chips arranged on each of the substrates onto the substrates; wherein the first projection modules project the wiring patterns onto different substrates, substantially simultaneously.

The configuration of the embodiment described later may be appropriately modified, and at least a part of the configuration may be replaced with another configuration. Further, the constituent elements whose arrangement is not particularly limited are not limited to the arrangement disclosed in the embodiment, and can be arranged at positions where the functions can be achieved.

### BRIEF DESCRIPTION OF DRAWINGS

FIG. 1 is a top view illustrating an outline of a wiring pattern formation system for the FO-WLP, including an exposure apparatus in accordance with a first embodiment;

FIG. 2 is a perspective view schematically illustrating a configuration of the exposure apparatus in accordance with the first embodiment;

FIG. 3A and FIG. 3B are diagrams for describing wiring patterns formed by the wiring pattern formation system;

FIG. 4 is a view for describing modules arranged on an optical surface plate;

FIG. 5A illustrates an optical system of an illumination/projection module, FIG. 5B schematically illustrates a DMD, FIG. 5C illustrates the DMD when the power is OFF, FIG. 5D is a view for describing a mirror in an ON state, and FIG. 5E is a view for describing the mirror in an OFF state;

FIG. 6 is an enlarged view of the vicinity of a projection system;

FIG. 7A is a schematic view illustrating a wafer WF in a state where all chips are placed at the design positions, and FIG. 7B is a schematic view illustrating a wafer WF in a state where the chips are arranged at positions shifted from the design positions;

FIG. 8 illustrates an example of the arrangement of measurement microscopes for measuring the positions of chips;

FIG. 9 illustrates an example of the arrangement of measurement microscopes for measuring the position of a substrate;

FIG. 10 is a block diagram illustrating a control system of the exposure apparatus in accordance with the embodiment;

FIG. 11A illustrates a first arrangement example of projection regions on which projection modules project wiring patterns, and FIG. 11B is a diagram for describing formation of the wiring patterns when the projection regions are arranged as illustrated in FIG. 11A;

FIG. 12A illustrates a second arrangement example of the projection regions of the projection modules, and FIG. 12B is a diagram for describing formation of wiring patterns when the projection regions are arranged as illustrated in FIG. 12A;

FIG. 13A illustrates a third arrangement example of the projection regions of the projection modules, and FIG. 13B is a diagram for describing formation of wiring patterns when the projection regions are arranged as illustrated in FIG. 13A;

FIG. 14A illustrates a fourth arrangement example of the projection regions of the projection modules, and FIG. 14B is a diagram for describing formation of wiring patterns when the projection regions are arranged as illustrated in FIG. 14A;

FIG. 15A illustrates a fifth arrangement example of the projection regions of the projection modules, FIG. 15B is a diagram for describing the arrangement of first and second projection modules included in the projection modules, and FIG. 15C is a diagram for describing the formation of wiring patterns when the projection regions are arranged as illustrated in FIG. 15A;

FIG. 16A illustrates a sixth arrangement example of the projection regions of the projection modules, FIG. 16B is a view for describing the arrangement of first and second projection modules included in the projection modules, and FIG. 16C is a view for describing formation of wiring patterns when the projection regions are arranged as illustrated in FIG. 16A;

FIG. 17 is a top view illustrating an outline of a wiring pattern formation system in accordance with a second embodiment;

FIG. 18A illustrates a first arrangement example of measurement microscopes in a chip measurement station in accordance with the second embodiment, and FIG. 18B illustrates a second arrangement example of the measurement microscopes;

FIG. 19 is a top view illustrating an outline of a wiring pattern formation system in accordance with a third embodiment;

FIG. 20 illustrates an example of arrangement of measurement microscopes in a chip measurement station in accordance with the third embodiment;

FIG. 21A to FIG. 21C are diagrams for describing the arrangement of a first projection module and a second projection module; and

FIG. 22A and FIG. 22B are views for describing the arrangement of wafers.

### DESCRIPTION OF EMBODIMENTS

### First Embodiment

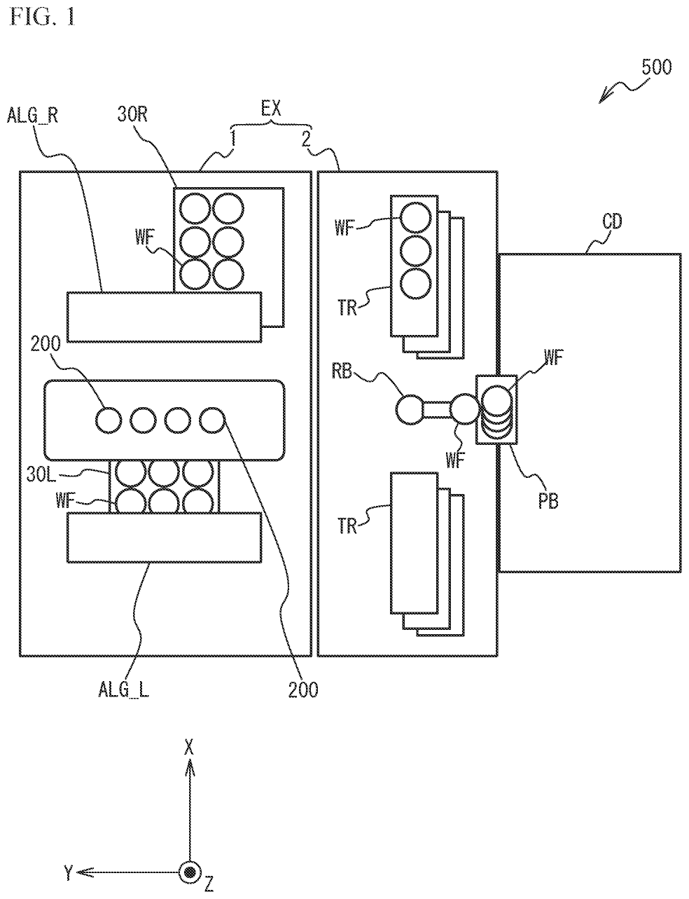

An exposure apparatus in accordance with a first embodiment will be described with reference to FIG. 1 to FIG. 16. In the following description, a substrate P indicates a rectangular substrate, and a wafer-shaped substrate is referred to as a wafer WF. In the following description, the normal direction of the substrate P or wafer WF placed on a substrate stage 30 described later is defined as a Z-axis direction, the direction in which the substrate P or wafer WF is scanned relative to a spatial light modulator (SLM) in the plane orthogonal to the Z-axis is defined as an X-axis direction, the direction orthogonal to the Z-axis and the X-axis is defined as a Y-direction, and the rotation (tilt) directions around the X-axis, Y-axis, Z-axis are defined as Ox, Oy, and Oz directions, respectively. Examples of the spatial light modulator include a liquid crystal element, a digital mirror device (DMD), and a magneto-optic spatial light modulator (MOSLM). An exposure apparatus EX in accordance with the first embodiment includes a DMD 204 as the spatial light modulator, but may include other spatial light modulators.

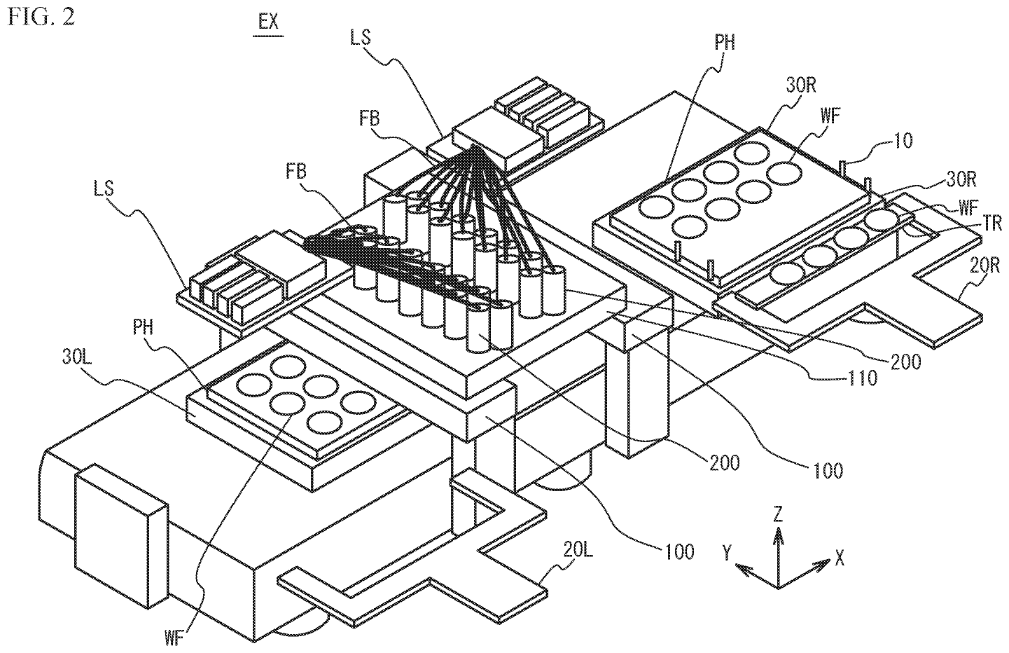

FIG. 1 is a top view illustrating an outline of a wiring pattern formation system 500 for the FO-WLP and FO-PLP, including the exposure apparatus EX in accordance with an embodiment. FIG. 2 is a perspective view schematically illustrating a configuration of the exposure apparatus EX.

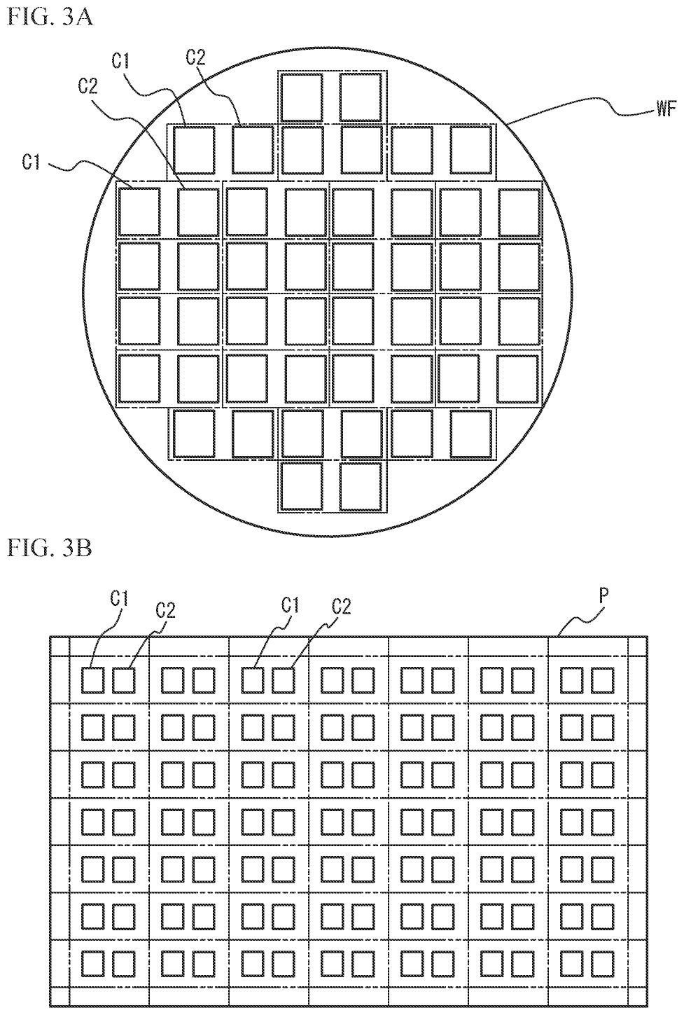

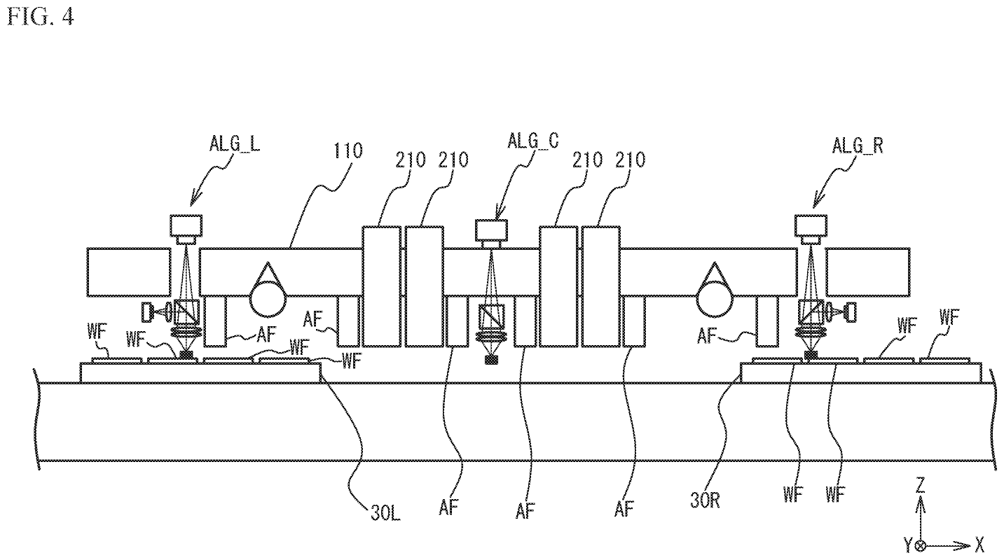

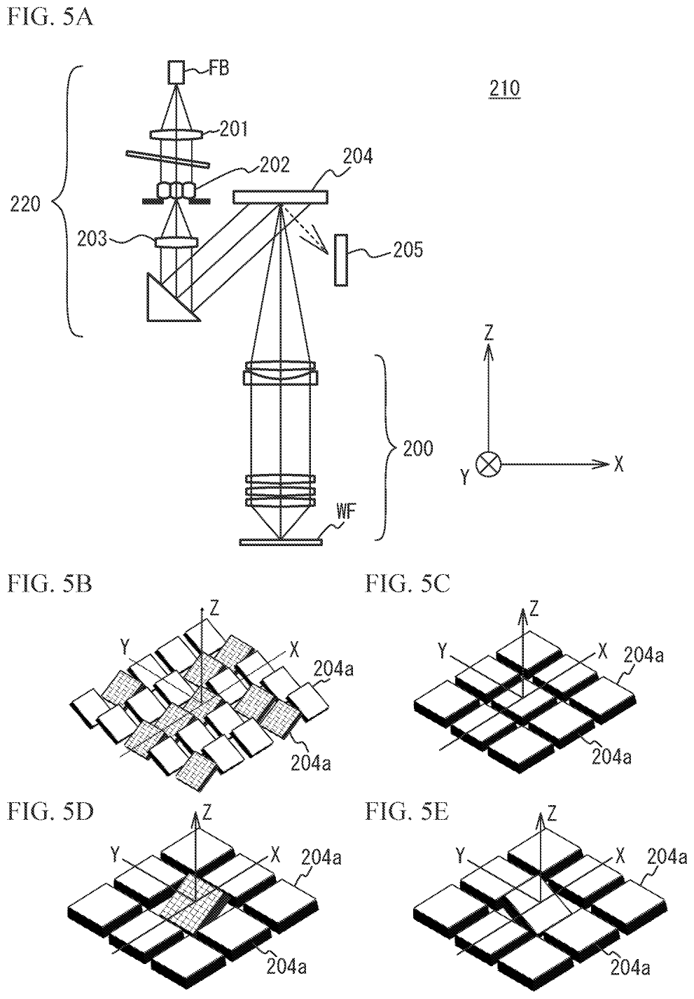

The wiring pattern formation system 500 is a system for forming wiring patterns for connecting chips arranged on the wafer WF as illustrated in FIG. 3A or for connecting chips arranged on the substrate P as illustrated in FIG. 3B.

In the present embodiment, a wiring pattern is formed to connect a chip C1 and a chip C2 included in each of sets of chips (indicated by double-dotted lines) placed on the wafer WF or the substrate P. In the present embodiment, the number of chips included in each set is two, but the number is not limited to this, and may be three or more.

The following describes a case where a wiring pattern for connecting chips arranged on the wafer WF is formed.

As illustrated in FIG. 1, the wiring pattern formation system 500 includes a coater/developer device CD and the exposure apparatus EX.

The coater/developer device CD coats the wafer WF with a photosensitive resist. The wafer WF coated with the resist is carried into a buffer section PB capable of stocking a plurality of wafers WF. The buffer section PB also serves as a delivery port for the wafer WF.

More specifically, the buffer section PB includes a carry-in section and a carry-out section. The wafers WF coated with a resist are carried into the carry-in section one by one from the coater/developer device CD. The wafers WF coated with the resist are carried into the carry-in section one by one at predetermined time intervals from the coater/developer device CD, and a plurality of wafers WF are loaded together on a tray TR described later, and therefore, the carry-in section functions as a buffer for storing the wafers WF.

The carry-out section functions as a buffer when the exposed wafer WF is carried out to the coater/developer device CD. The coater/developer device CD can take out the exposed wafers WF only one at a time. Then, the tray TR on which a plurality of exposed wafers WF are placed is placed in the carry-out section. This allows the coater/developer device CD to take out the exposed wafers WF one by one from the tray TR.

The exposure apparatus EX includes a main unit 1 and a substrate exchange unit 2. As illustrated in FIG. 1, a robot RB is installed in the substrate exchange unit 2. The robot RB arranges a plurality of wafers WF placed in the buffer section PB onto one tray TR.

As illustrated in FIG. 1 and FIG. 2, in the first embodiment, four wafers WF in three rows can be placed on each of substrate stages 30R and 30L described later. The tray TR in accordance with the first embodiment is a lattice-shaped tray with which four wafers WF in one row can be sequentially placed on each of the substrate stages 30R and 30L. The tray TR may be a tray with which the wafers WF can be placed at a time on the entire surface of each of the substrate stages 30R and 30L (that is, a tray on which four wafers WF in three rows can be arranged). Hereinafter, the substrate stages 30R and 30L are referred to as the substrate stages 30 when it is not necessary to distinguish between the substrate stages 30R and 30L in particular.

As illustrated in FIG. 2, the substrate exchange unit 2 includes exchange arms 20R and 20L. The exchange arm 20R carries in and out the wafers WF (more specifically, the tray TR on which the wafers WF are placed) to and from a substrate holder PH of the substrate stage 30R, and the exchange arm 20L carries in and out the wafers WF to and from the substrate holder PH of the substrate stage 30L. In the following description, the exchange arms 20R and 20L are referred to as exchange arms when it is not necessary to distinguish them in particular. In addition, the substrate holder PH is not illustrated in the drawings other than FIG. 2.

Generally, each of the exchange arms 20R and 20L includes a carry-in arm for carrying in the tray TR and a carry-out arm for carrying out the tray TR. Thus, the tray TR can be exchanged at high speed. When the wafers WF are carried in, substrate exchange pins 10 support the lattice-shaped tray TR. When the substrate exchange pins 10 are lowered, the tray TR is sunk into a groove (not illustrated) formed in the substrate stage 30, and the wafers WF are sucked and held by the substrate holder PH on the substrate stage 30. When a row of substrates is placed on the tray TR as illustrated in FIG. 2, the positions of the substrate stages 30R and 30L or the positions of the exchange arms 20R and 20L are changed in accordance with the position where each tray TR is placed on the substrate stages 30R and 30L.

Next, the main unit 1 will be described. FIG. 4 is a view for describing modules arranged on an optical surface plate 110 of the main unit 1. As illustrated in FIG. 4, a plurality of projection systems 210, autofocus systems AF, and alignment systems ALG_R, ALG_L, and ALG_C are arranged on the optical surface plate 110 kinematically supported on a column 100.

FIG. 5A illustrates an optical system of the projection system 210. The projection system 210 includes an illumination module 220 and a projection module 200. The illumination module 220 includes a collimator lens 201, a fly-eye lens 202, a main condenser lens 203, and the DMD 204.

The laser light emitted from a light source LS (see FIG. 2) is taken into the projection module 200 through a delivery fiber FB. The laser light passes through the collimator lens 201, the fly-eye lens 202, and the main condenser lens 203, and illuminates the DMD 204 substantially uniformly.

FIG. 5B schematically illustrates the DMD 204, and FIG. 5C illustrates the DMD 204 when the power is OFF. In FIG. 5B to FIG. 5E, the mirror in the ON state is indicated by hatching.

The DMD 204 has a plurality of micromirrors 204a that can be controlled to change the reflection angles thereof. Each micromirror 204a is turned on by tilting around the Y-axis. FIG. 5D illustrates a case where only the center micromirror 204a is in the ON state, and other micromirrors 204a are in a neutral state (a state other than the ON state and the OFF state). Each micromirror 204a is turned off by tilting around the X-axis. FIG. 5E illustrates a case where only the center micromirror 204a is turned off and other micromirrors 204a are in the neutral state. The DMD 204 generates an exposure pattern of wiring lines connecting the chips (hereinafter referred to as a wiring pattern) by switching the ON and OFF states of each micromirror 204a.

The illumination light reflected by the mirror in the OFF state is absorbed by an OFF light absorbing plate 205 as illustrated in FIG. 5A. The projection module 200 has a magnification power for projecting one pixel of the DMD 204 in a predetermined size, and can slightly correct the magnification by focusing by Z-axis driving of the lens and driving some of the lenses. The DMD 204 itself can be driven in the X-axis direction, the Y-axis direction, and the Oz direction by controlling an X, Y, and θ stage (not illustrated) on which the DMD 204 is mounted, and corrects, for example, a deviation from a target value of the substrate stage 30.

Although the DMD 204 has been described as an example of the spatial light modulator and thus as a reflective type that reflects laser light, the spatial light modulators may be a transmissive type that transmits laser light or a diffractive type that diffracts laser light. The spatial light modulator can modulate the laser light spatially and temporally.

Referring back to FIG. 4, the autofocus systems AF are arranged so as to sandwich the projection system 210. This allows measurement by the autofocus systems AF before the exposure operation to form the wiring patterns that connect the chips placed on the wafer WF, regardless of the scanning direction of the wafer WF.

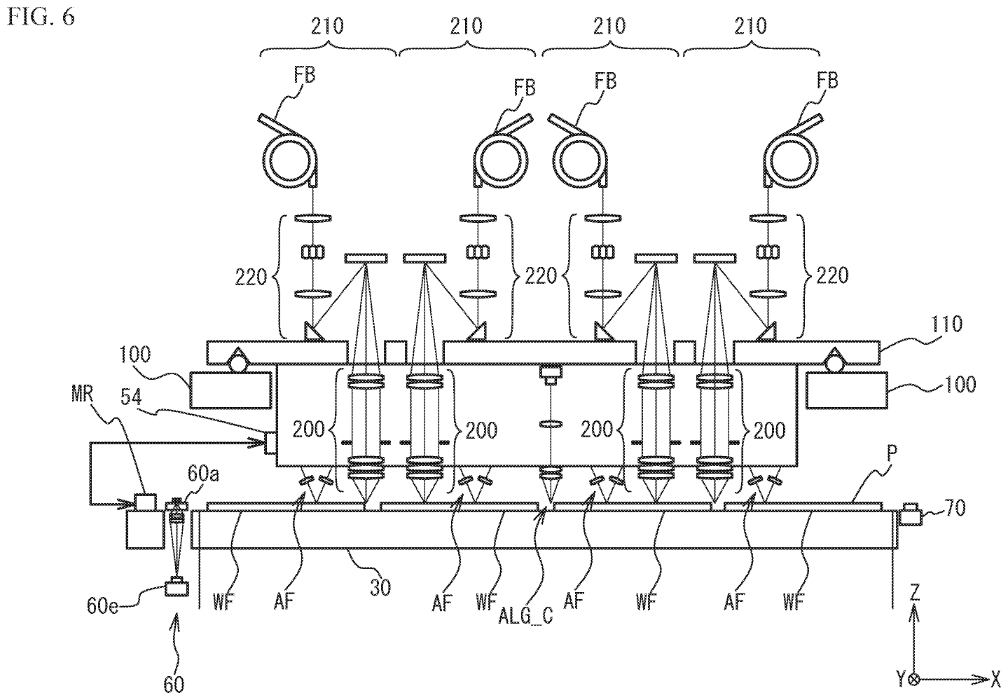

FIG. 6 is an enlarged view of the vicinity of the projection system 210. As illustrated in FIG. 6, a fixed mirror 54 for measuring the position of the substrate stage is provided near the projection module 200.

As illustrated in FIG. 6, the substrate stage 30 is provided with an alignment device 60. The alignment device 60 includes a reference mark 60a, a two-dimensional image sensor 60e, and the like. The alignment device 60 is used for measurement and calibration of the positions of various modules, and is also used for calibration of the alignment systems ALG_R, ALG_L, and ALG_C arranged on the optical surface plate 110.

The measurement and calibration of the position of each module is performed by projecting a DMD pattern for calibration onto the reference mark 60a of the alignment device 60 by the projection module 200 and measuring the relative position between the reference mark 60a and the DMD pattern.

Further, the calibration of the alignment systems ALG_R, ALG_L, and ALG_C can be performed by measuring the reference mark 60a of the alignment device 60 with the alignment systems ALG_R, ALG_L, and ALG_C. That is, by measuring the reference mark 60a of the alignment device 60 with the alignment systems ALG_R, ALG_L, and ALG_C, the positions of the alignment systems ALG_R, ALG_L, and ALG_C can be obtained. Furthermore, the relative position with respect to the position of the module can be obtained using the reference mark 60a. The substrate stage 30 is provided with a moving mirror MR used to measure the position of the substrate stage 30, a DM monitor 70, and the like.

Each of the alignment systems ALG-R and ALG-L measures the positions of the chips on each wafer WF sucked by the substrate holder PH or the positions of the pads of the chips to be wired, with reference to the reference mark 60a of the alignment device 60. More particularly, the alignment systems ALG_R and ALG_L measure the position of each chip based on the design position of each chip, using the reference mark 60a as a reference. The measurement result is output to a data generation device 300 described later.

The measurement of the position of each chip will be described below.

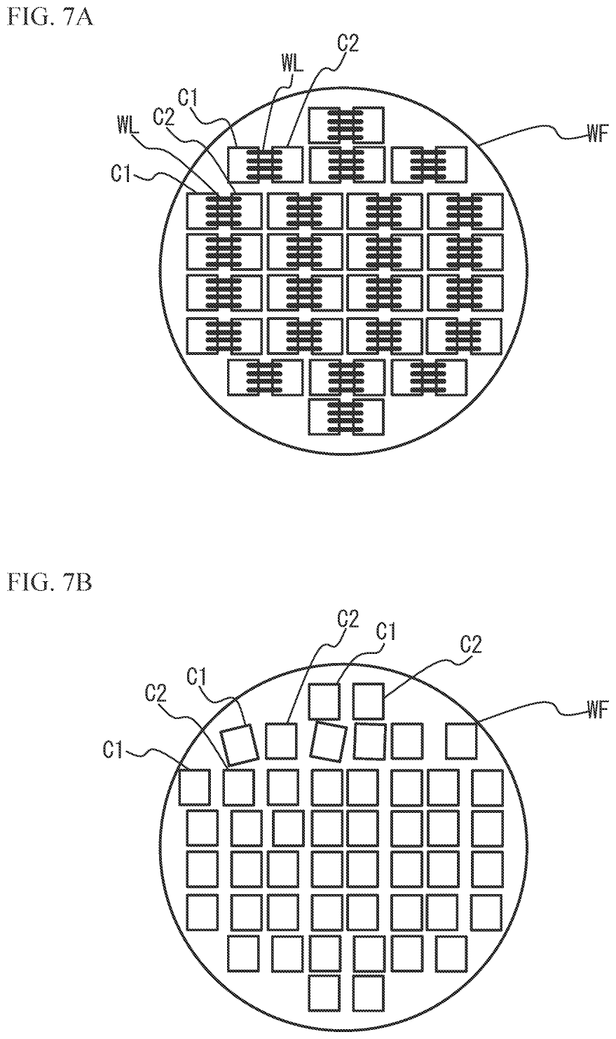

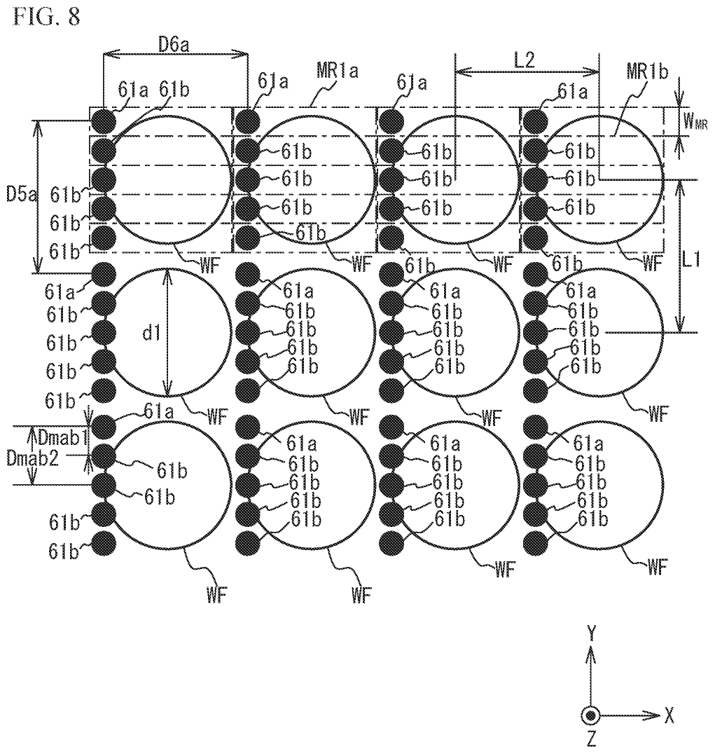

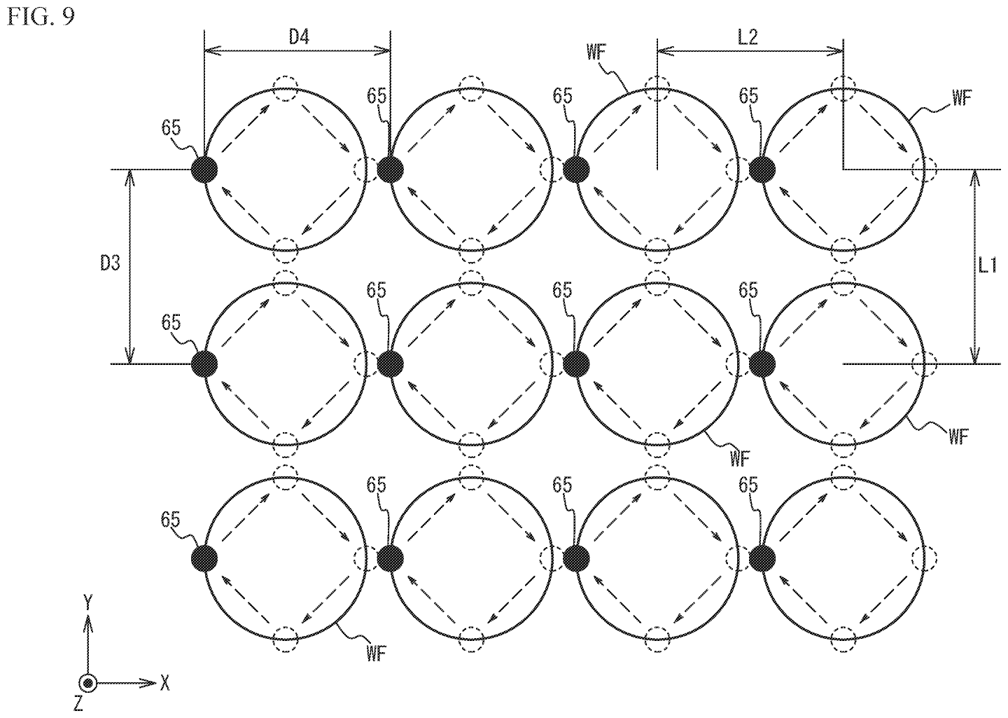

FIG. 7A is a schematic view illustrating the wafer WF in a state where all chips are arranged at positions in design (hereinafter, referred to as design positions). As illustrated in FIG. 7A, the wiring pattern WL connecting the chip C1 and the chip C2 is exposed (formed) by the exposure apparatus EX. Here, in the FO-WLP, since the chips are fixed with a mold material such as a resin on the wafer WF, as illustrated in FIG. 7B, the position of each chip may be shifted from the design position. In this case, if the DMD 204 is controlled and the wiring pattern is exposed using data indicating the wiring pattern that connects the chips at the design positions (hereinafter, referred to as design value data), the wiring pattern may shift from the positions of the pads, resulting in a poor connection or short circuit.

Therefore, in the present embodiment, the alignment system ALG_R or ALG_L measures the positions of the chips included in each of the sets of the chips arranged on the wafer WF. The data generation device 300 generates wiring pattern data by correcting a part of the design value data based on the measurement result obtained from the alignment system ALG_R or ALG_L.

Each of the alignment systems ALG_R and ALG_L include a plurality of measurement microscopes 61a and 61b.

(Arrangement Example of Measurement Microscopes 61a and 61b)

The arrangement of the measurement microscopes 61a and 61b provided in each of the alignment systems ALG_R and ALG_L will be described. FIG. 8 illustrates an example of the arrangement of the measurement microscopes 61a and 61b. In FIG. 8, the lenses of the measurement microscopes 61a and 61b are illustrated as the measurement microscopes 61a and 61b. A case will be described in which 4 columns×3 rows of the wafers WF are arranged on the substrate stage 30 as illustrated in FIG. 8. The wafers WF are arranged at intervals L1 in the Y-axis direction, and the wafers WF are arranged at intervals L2 in the X-axis direction.

The first measurement microscopes 61a of the measurement microscopes are arranged so as to be able to measure the positions of the chips on different wafers WF substantially simultaneously.

The first measurement microscopes 61a are arranged so as to be able to measure the positions of semiconductor chips on different wafers WF substantially simultaneously. In the present embodiment, the first measurement microscopes 61a are provided corresponding to the wafers WF, respectively. Specifically, the first measurement microscopes 61a are arranged in a matrix of 4 columns×3 rows.

The interval D5a between the first measurement microscopes 61a adjacent to each other in the Y-axis direction is substantially equal to the interval L1 at which the wafers WF are arranged in the Y-axis direction, and the interval D6a between the first measurement microscopes 61a adjacent to each other in the X-axis direction is substantially equal to the interval L2 at which the wafers WF are arranged in the X-axis direction. By arranging the first measurement microscopes 61a in this manner, the positions of the chips arranged on each of 12 wafers WF can be measured substantially simultaneously.

In the present embodiment, each of the alignment systems ALG_R and ALG_L further includes a plurality of second measurement microscopes 61b corresponding to the first measurement microscopes 61a. The second measurement microscopes 61b measure regions different from the region measured by the corresponding first measurement microscope 61a on the same wafer WF as the wafer WF measured by the corresponding first measurement microscope 61a, substantially simultaneously with the corresponding first measurement microscope 61a.

In the example of FIG. 8, four second measurement microscopes 61b are provided for each of the first measurement microscopes 61a. Each second measurement microscope 61b is arranged at a position shifted from the corresponding first measurement microscope 61a by an integral multiple of the width W_{MR} in the Y-axis direction of the measurement region MR1a. That is, in FIG. 8, the interval Dmab1 between the first measurement microscope 61a and the second measurement microscope 61b closest to the first measurement microscope 61a among the second measurement microscopes 61b corresponding to the first measurement microscope 61a is substantially equal to W_{MR} (1×W_{MR}). The interval Dmab2 between the first measurement microscope 61a and the second measurement microscope 61b second-closest to the first measurement microscope 61a is substantially equal to two times W_{MR}. Further, the width W_{MR} of the measurement region MR1a in the Y-axis direction is substantially equal to an integral division (one-fifth in FIG. 8) of the diameter d of the wafer WF.

In the example of FIG. 8, since the positions of the chips on 12 wafers WF can be measured in a single scan, the time required to measure the positions of the chips can be shorten, for example, as compared with the case where the positions of the chips on 12 wafers WF are measured by one measurement microscope 61. More specifically, in the example of FIG. 8, the positions of the chips on 12 wafers WF can be measured in one-sixtieth of the time required for one measurement microscope 61 to measure the positions of the chips on 12 wafers WF. Therefore, the throughput in the formation of the wiring patterns can be improved. The throughput in the formation of the wiring patterns is a throughput in the process related to the formation of the wiring patterns, and the process related to the formation of the wiring patterns includes the measurement process of the chip positions, the measurement process of the positions of the wafers WF, and the formation process of the wiring patterns.

The alignment system ALG_C measures the positions of the wafers WF placed on the substrate holder of the substrate stage 30 before the start of exposure, with reference to the reference mark 60a of the alignment device 60. Based on the measurement results by the alignment system ALG_C, the positional shifts of the wafers WF with respect to the substrate stage 30 are detected, and the exposure start position and the like are changed.

Although the alignment system ALG_C measures the positions of the wafers WF placed on the substrate holder PH of the substrate stage 30 before the start of exposure, using the reference mark 60a (see FIG. 8) of the alignment device 60 as a reference, the measurement by the alignment system ALG_C can be omitted if the positional relationship between the substrate stage 30 and the wafers WF does not change. If the X, Y, θ, and magnification of each wafer WF placed on the substrate holder PH slightly deviate, the current state of the wafer WF is measured by the alignment system ALG_C, and the difference from the state of the wafer WF measured by the alignment system ALG_R or ALG_L (the state of the wafer WF used for generation of the wiring pattern data) is corrected by changing the state of the X, Y, 0 stage on which the DMD 204 is mounted and the magnification of the lens. This eliminates the need to rewrite the wiring pattern data, and the process can smoothly shift to exposure.

In the present embodiment, the alignment system ALG_C includes a plurality of measurement microscopes 65. The measurement microscopes 65 measure the positions of different substrates substantially simultaneously.

(Arrangement of Measurement Microscopes 65)

FIG. 9 illustrates an example of the arrangement of the measurement microscopes 65 included in the alignment system ALG_C. As illustrated in FIG. 9, in the present embodiment, the measurement microscopes 65 are provided so as to correspond to the wafers WF, respectively. That is, the measurement microscopes 65 are arranged in a matrix of 4 columns×3 rows. The interval D3 between the measurement microscopes 65 adjacent to each other in the Y-axis direction is substantially equal to the interval L1 at which the wafers WF are arranged in the Y-axis direction, and the interval D4 between the measurement microscopes 65 adjacent to each other in the X-axis direction is substantially equal to the interval L2 at which the wafers WF are arranged in the X-axis direction.

Each of the measurement microscopes 65 arranged in this manner moves relative to the wafer WF as the substrate stage 30 moves, as indicated by the dashed arrows, and measures four locations on the corresponding wafer WF. This makes it possible to calculate six parameters of the wafer WF placed on the substrate holder PH: the X-axis direction shift (X), the Y-axis direction shift (Y), the rotation (Rot), the X-axis direction magnification (X_Mag), the Y-axis direction magnification (Y_Mag), and the orthogonality (Oth).

In the alignment system ALG_C, since the measurement microscopes 65 are provided so as to correspond to the wafers WF, respectively, the positions of all wafers WF can be measured in a short time, for example, as compared to the case where the positions of the wafers WF are measured by one measurement microscope 65.

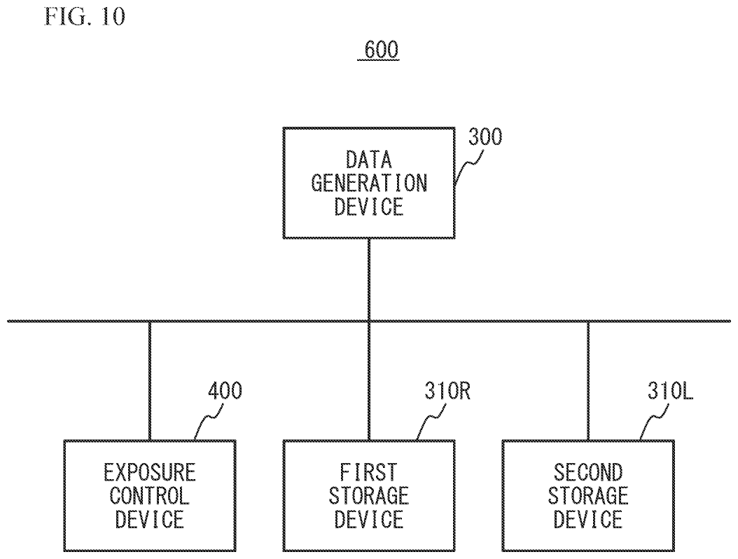

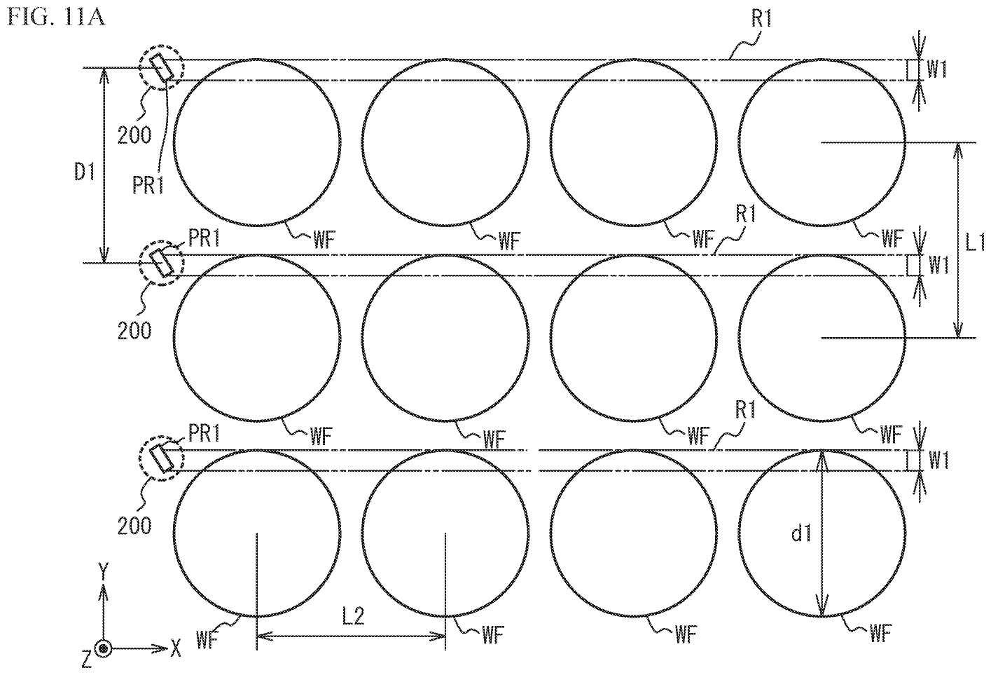

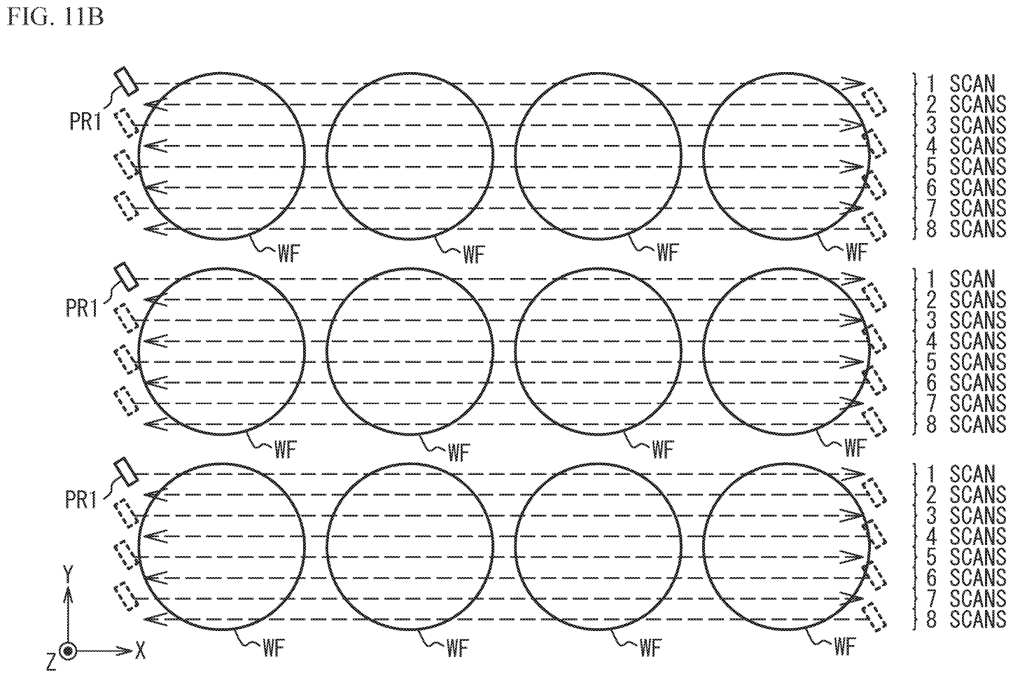

FIG. 10 is a block diagram illustrating a control system 600 of the exposure apparatus EX in accordance with the present embodiment. As illustrated in FIG. 10, the control system 600 includes the data generation device 300, a first storage device 310R, a second storage device 310L, and an exposure control device 400.

The data generation device 300 receives the measurement results of the positions of the chips or the positions of the pads of the chips provided on the wafers WF placed on the substrate holder of the substrate stage 30 from the alignment systems ALG_R and ALG_L. The data generation device 300 determines wiring patterns for connecting the chips based on the measurement result of the position of each chip, and generates control data used to control the DMD 204 when forming the determined wiring patterns. In the present embodiment, the alignment system ALG_R or ALG_L measures the positions of the chips included in each of the sets of the chips arranged on the wafers WF. The data generation device 300 generates wiring pattern data in which a part of the design value data is corrected based on the measurement results obtained from the alignment system ALG_R or ALG_L.

The generated wiring pattern data is stored in the first storage device 310R or the second storage device 310L. The first storage device 310R and the second storage device 310L are, for example, solid state drives (SSDs).

The first storage device 310R stores wiring pattern data used to control the DMD 204 when exposing the wafers WF placed on the substrate stage 30R. The second storage device 310L stores the wiring pattern data used to control the DMD 204 when exposing the wafers WF placed on the substrate stage 30L. The wiring pattern data stored in the first storage device 310R or the second storage device 310L is transferred to the exposure control device 400.

The exposure control device 400 controls the projection modules 200 to expose the wiring patterns onto the wafers WF. More specifically, the exposure control device 400 substantially simultaneously exposes the respective wiring patterns on different wafers WF using the projection modules 200.

Therefore, in the present embodiment, the projection modules 200 are arranged so that the respective projection regions of the projection modules 200 are positioned on different wafers WF. Hereinafter, an example of the arrangement of the projection regions and the arrangement of the projection modules 200 for achieving the arrangement will be described.

(First Arrangement Example)

FIG. 11A illustrates a first arrangement example of the projection regions onto which the projection modules 200 project the wiring patterns. In FIG. 11A, the projection module 200 is indicated by a dotted line, and a projection region PR1 where the projection module 200 projects the wiring pattern onto the wafer WF is indicated by a solid line. In FIG. 11A, a region R1 where the wiring pattern is exposed by one scan of the substrate stage 30 is indicated by a dash-double-dot line. The same applies to the subsequent drawings. One scan is defined as moving the substrate stage 30 from the +X side to the −X side by a predetermined distance, or moving the substrate stage from the −X side to the +X side by a predetermined distance. Hereinafter, the distance by which the substrate stage 30 moves in one scan will be referred to as a scanning distance.

As illustrated in FIG. 11A, the wafers WF are arranged at intervals L1 in the Y-axis direction (non-scanning direction), and are arranged at intervals L2 in the X-axis direction (scanning direction). The diameter of the wafer WF is represented by d1.

As illustrated in FIG. 11A, in the first arrangement example, the projection regions PR1 are arranged so that the interval D1 between the projection regions PR1 adjacent to each other in the Y-axis direction is substantially equal to the interval L1 at which the wafers WF are arranged in the Y-axis direction (D1=L1). The arrangement of the projection regions PR1 illustrated in FIG. 11A can be achieved by, for example, arranging the projection modules 200 at intervals D1 substantially equal to the interval L1 in the Y-axis direction.

FIG. 11B is a diagram for describing formation (exposure) of the wiring patterns when the projection regions PR1 are arranged as illustrated in FIG. 11A. In FIG. 11B, the movement of the projection region PR1 relative to the wafer WF is indicated by a broken line arrow. The number of times of scanning of the substrate stage 30 is presented at the right end.

In the first arrangement example, each projection module 200 projects and exposes the wiring patterns onto four wafers WF in one scan.

As illustrated in FIG. 11A, it is assumed that the width in the Y-axis direction (non-scanning direction) of the region R1 exposed by each projection module 200 in one scan is W1, and the diameter d1 of the wafer WF is eight times W1. In this case, the wiring patterns can be formed on all the wafers WF in eight scans.

In the example of FIG. 11A and FIG. 11B, when only one projection module 200 is provided, 24 scans are required to form the wiring patterns on all the wafers WF. On the other hand, according to the first arrangement example as described above, since the wiring patterns can be exposed on all the wafers WF in eight scans, the time required for forming the wiring patterns can be shortened.

(Second Arrangement Example)

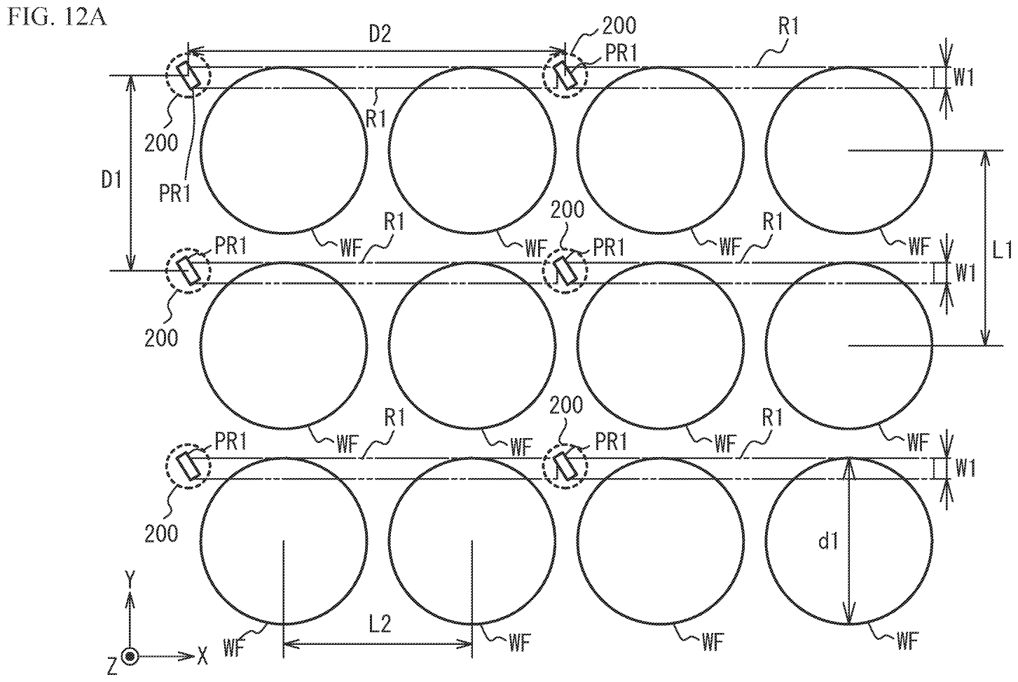

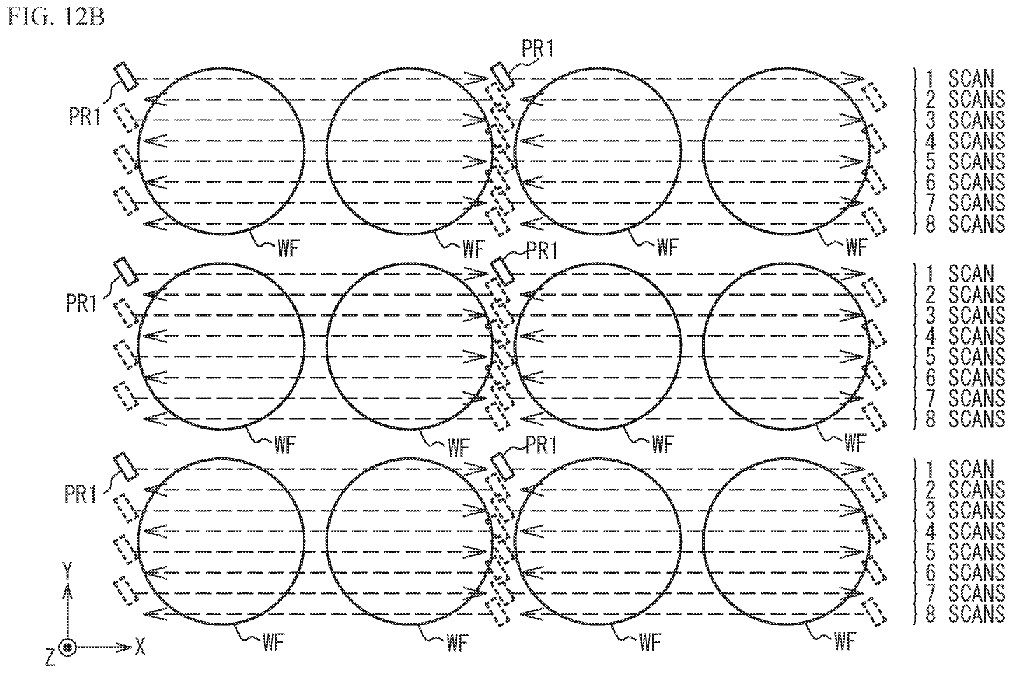

FIG. 12A illustrates a second arrangement example of the projection regions of the projection modules 200.

In the second arrangement example illustrated in FIG. 12A, the projection regions PR1 of the projection modules 200 are arranged in a matrix of 2 rows×3 columns. The interval between the projection regions PR1 adjacent to each other in the Y-axis direction is D1, and the interval between the projection regions PR1 adjacent to each other in the X-axis direction is D2. The interval D1 in the Y-axis direction is substantially equal to the interval L1 at which the wafers WF are arranged in the Y-axis direction (D1=L1), and the interval D2 in the X-axis direction is substantially equal to two times the interval L2 at which the wafers WF are arranged in the X-axis direction (D2=2×L2). The arrangement of the projection regions PR1 illustrated in FIG. 12A can be achieved by, for example, arranging the projection modules 200 at intervals D1 substantially equal to the interval L1 in the Y-axis direction and arranging the projection modules 200 at intervals D2 substantially equal to two times the interval L2 in the X-axis direction.

FIG. 12B is a diagram illustrating formation of the wiring patterns when the projection regions PR1 are arranged as in FIG. 12A. As illustrated in FIG. 12A, a case is considered where the width in the Y-axis direction (non-scanning direction) of the region R1 exposed by each projection module 200 in one scan is W1, and the diameter d1 of the wafer WF is substantially equal to eight times W1. In this case, the wiring patterns can be formed on all the wafers WF in eight scans.

In the second arrangement example, since the projection modules 200 are arranged also in the X-axis direction, the scanning distance of the substrate stage 30 is shorter than that in the first arrangement example (a half of the scanning distance in the first arrangement example). Therefore, the time required for forming the wiring pattern can be reduced compared with that of the first arrangement example.

(Third Arrangement Example)

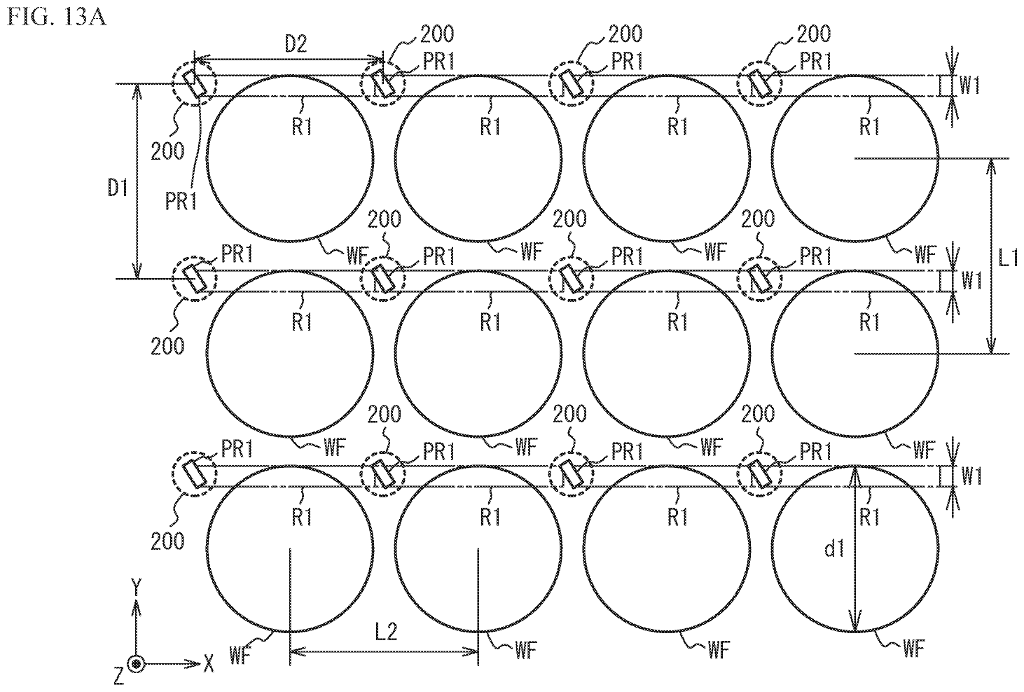

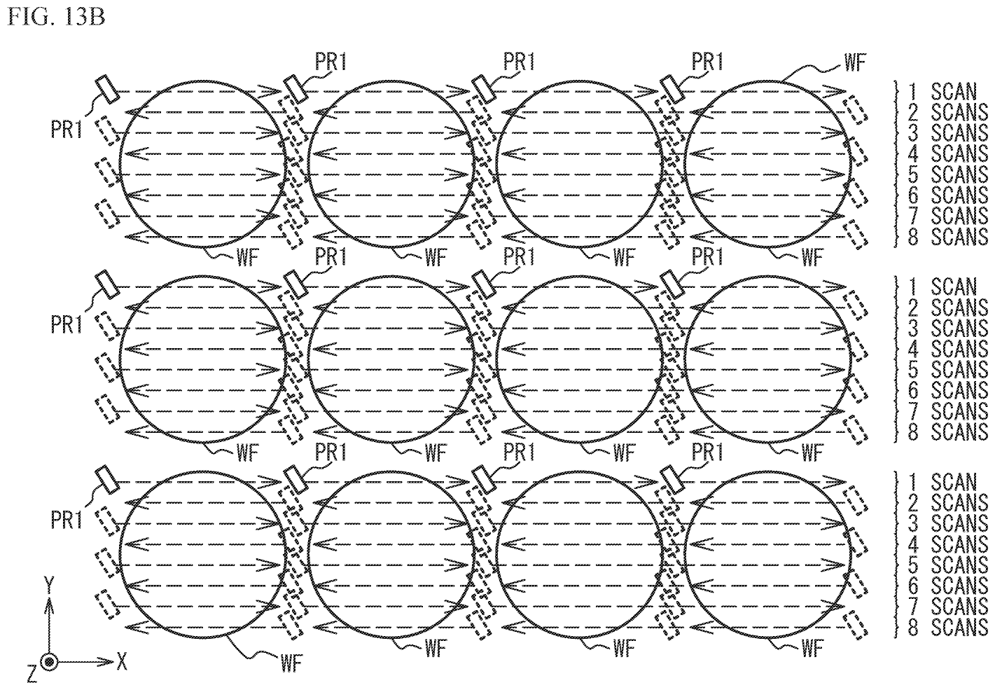

FIG. 13A illustrates a third arrangement example of the projection regions of the projection modules 200.

In the third arrangement example illustrated in FIG. 13A, the projection modules 200 are arranged in a matrix of 4 columns×3 rows so as to correspond to the wafers WF, respectively. The interval between the adjacent projection regions PR1 in the Y-axis direction is D1, and the interval between the adjacent projection regions PR1 in the X-axis direction is D2. The interval D1 in the Y-axis direction is substantially equal to the interval L1 at which the wafers WF are arranged in the Y-axis direction, and the interval D2 in the X-axis direction is substantially equal to the interval L2 at which the wafers WF are arranged in the X-axis direction. The arrangement of the projection regions PR1 illustrated in FIG. 13A can be achieved by arranging the projection modules 200 at intervals D1 substantially equal to the interval L1 in the Y-axis direction and arranging the projection modules 200 at intervals D2 substantially equal to the interval L2 in the X-axis direction.

FIG. 13B is a diagram for describing the formation of the wiring patterns when the projection regions PR1 are arranged as illustrate in FIG. 13A. As illustrated in FIG. 13A, it is assumed that the width in the Y-axis direction (non-scanning direction) of the region R1 exposed by each projection module 200 in one scan is W1, and the diameter d1 of the wafer WF is substantially equal to eight times W1. In this case, the wiring patterns can be formed on all the wafers WF in eight scans.

In the third arrangement example, the projection regions PR1 are arranged at intervals D2 substantially equal to the interval L1 at which the wafers WF are arranged in the X-axis direction. This configuration allows the scanning distance of the substrate stage 30 to be even shorter than in the second arrangement example (one-half of the scanning distance in the second arrangement example), so that the wiring patterns can be formed on all the wafers WF in a shorter time than in the second arrangement example illustrated in FIG. 12A. In other words, since each of the projection modules 200 exposes the corresponding wafer WF, it is possible to expose 12 wafers WF in the same time as in the case of exposing one wafer WF.

Further, in the third arrangement example, the size of the exposure apparatus EX can be made smaller than in the arrangement examples illustrated in FIG. 11A and FIG. 12A, and the throughput can be further improved. The reason for this will be described below.

As illustrated in FIG. 9, the positions of the wafers WF are measured before the start of exposure, and a correction value for correcting the positional shift of each wafer WF is determined. In this case, as illustrated in FIG. 11A and FIG. 12A, when each projection module 200 exposes a plurality of wafers WF in one scanning exposure, it is necessary to perform optical correction based on the correction value corresponding to the wafer WF when exposing different wafers WF. Therefore, for example, every time the wafer WF to be exposed is changed, the state of the X, Y, θ stage on which the DMD 204 is mounted and the magnification of the lens are required to be changed based on the correction value. On the other hand, as illustrated in FIG. 13A, when the wafer WF to be exposed by each projection module 200 is predetermined, the correction value does not change, and therefore, it is not necessary to change the state of the X, Y, θ stage on which the DMD 204 is mounted and the magnification of the lens. Therefore, it is not necessary to set the interval between the wafers WF to an interval in consideration of the driving time of the X, Y, θ stage of the DMD 204 and the time required to change the lens magnification due to the switching of the correction values, which leads to the miniaturization of the exposure apparatus EX and the improvement of the throughput.

(Fourth Arrangement Example)

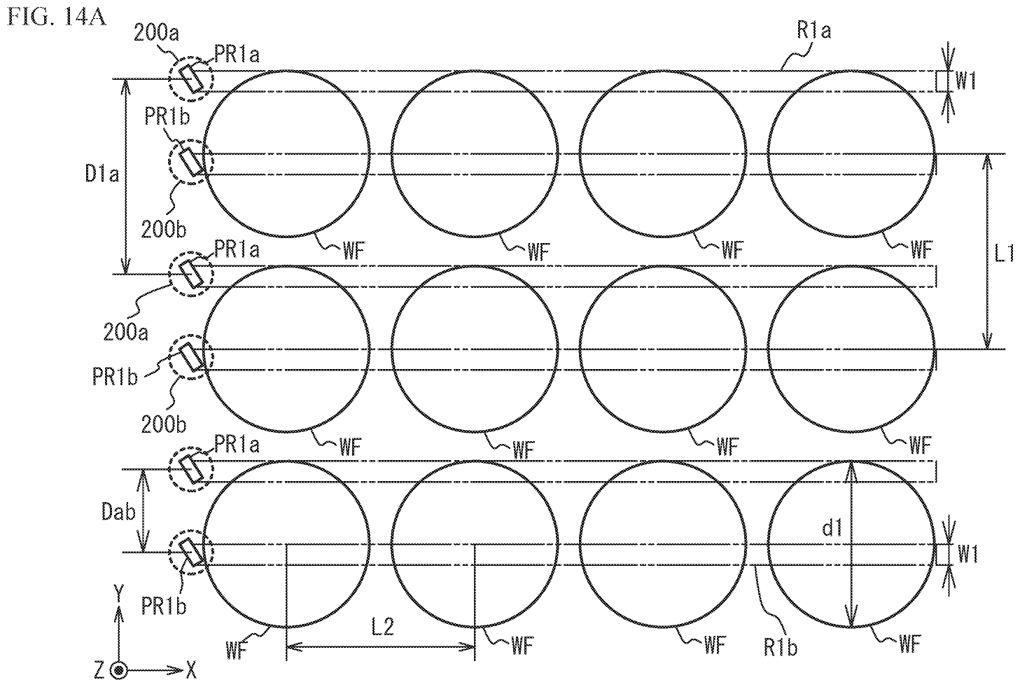

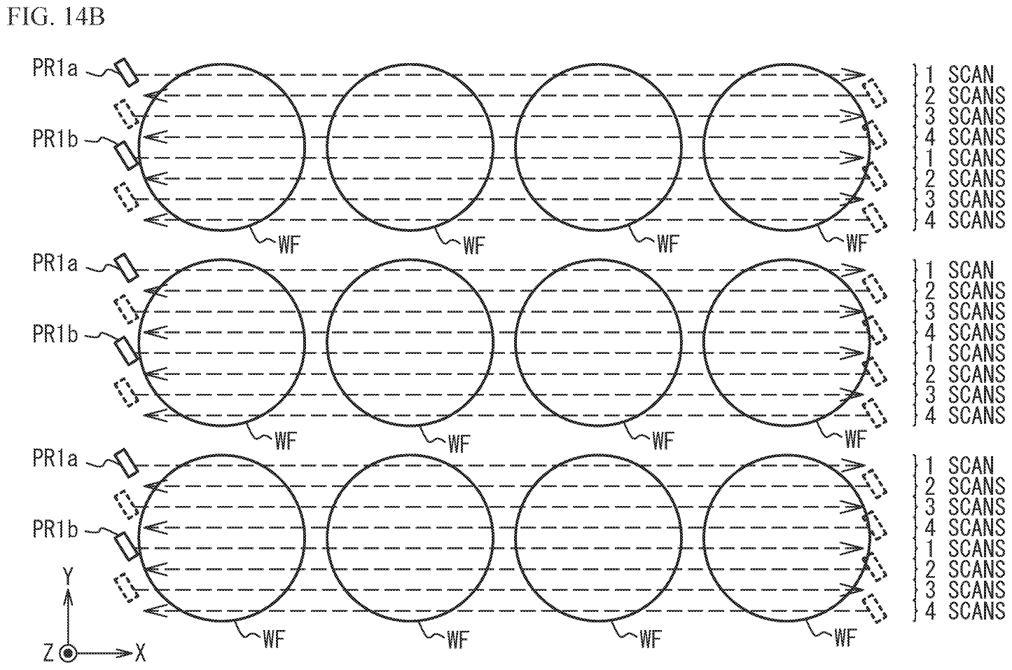

FIG. 14A illustrates a fourth arrangement example of the projection regions of the projection modules 200. In the fourth arrangement example illustrated in FIG. 14A, a plurality of first projection modules 200a and a plurality of second projection modules 200b corresponding to the first projection modules 200a, respectively are provided as the projection modules 200.

The projection regions PR1a of the first projection modules 200a project their respective wiring patterns onto different substrates substantially simultaneously. The interval between the adjacent projection regions PR1a in the Y-axis direction among the projection regions PR1a of the first projection modules 200a is D1a, and the interval D1a is substantially equal to the interval L1 at which the wafers WF are arranged in the Y-axis direction. The arrangement of the projection regions PR1a illustrated in FIG. 14A can be achieved by, for example, arranging the first projection modules 200a at intervals D1a substantially equal to the intervals L1 in the Y-axis direction.

Each of the second projection modules 200b projects its wiring pattern on the same wafer WF as the wafer WF on which the corresponding first projection module 200a projects the wiring pattern, substantially simultaneously with the corresponding first projection module 200a.

The projection region PR1b of each second projection module 200b is arranged at a position shifted from the projection region PR1a of the corresponding first projection module 200a by an integral division of the diameter d1 of the wafer WF. In the example of FIG. 14A, the projection region PR1b of the second projection module 200b is arranged at a position shifted from the projection region PR1a of the corresponding first projection module 200a by substantially d1/2. In other words, the interval Dab between the projection regions PR1a and PR1b is substantially equal to an integral division (one-half in FIG. 14A) of the diameter d1 of the wafer WF. The arrangement of the projection regions PR1b illustrated in FIG. 14A can be achieved by, for example, arranging each second projection module 200b at a position shifted from the corresponding first projection module 200a by an integral division of the diameter d1 of the wafer WF in the Y-axis direction.

FIG. 14B is a diagram for describing formation of the wiring patterns when the projection region PR1a and the projection region PR1b are arranged as in FIG. 14A. As illustrated in FIG. 14B, it is assumed that the widths in the Y-axis direction (non-scanning direction) of the region R1a exposed by the first projection module 200a and the region R1b exposed by the second projection module 200b in one scan are W1, and the diameter d1 of the wafer WF is substantially equal to eight times W1. In this case, the wiring patterns can be formed on all the wafers WF in four scans.

In this manner, in the fourth arrangement example, since the wiring patterns can be formed on all the wafers WF in four scans, the wiring patterns can be formed on all the wafers WF in a shorter time than in the first arrangement example illustrated in FIG. 11A.

(Fifth Arrangement Example)

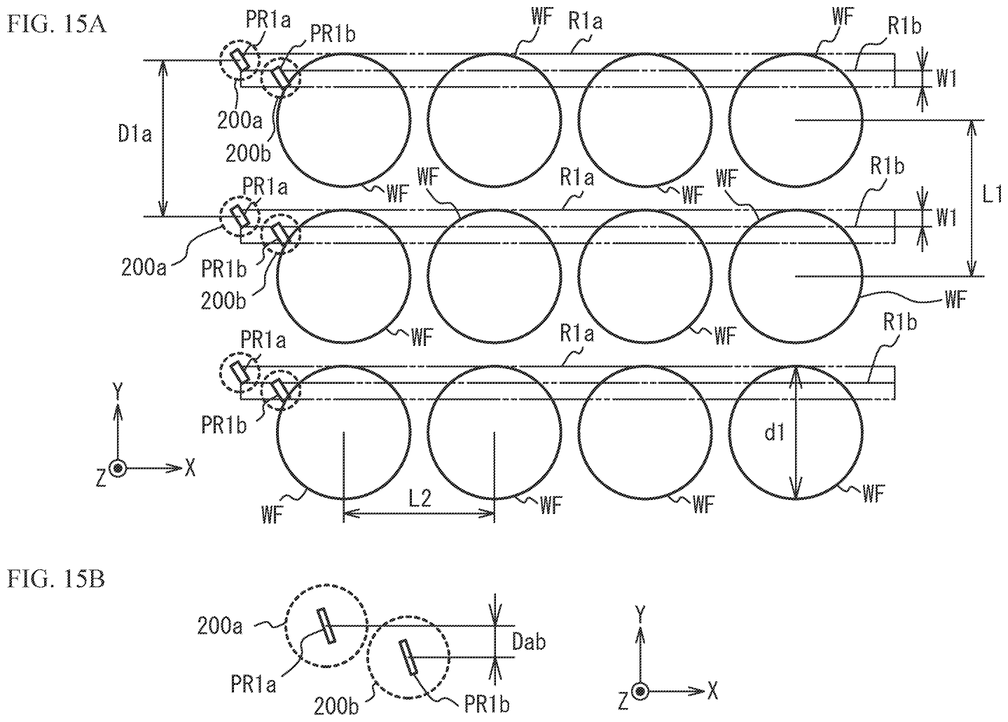

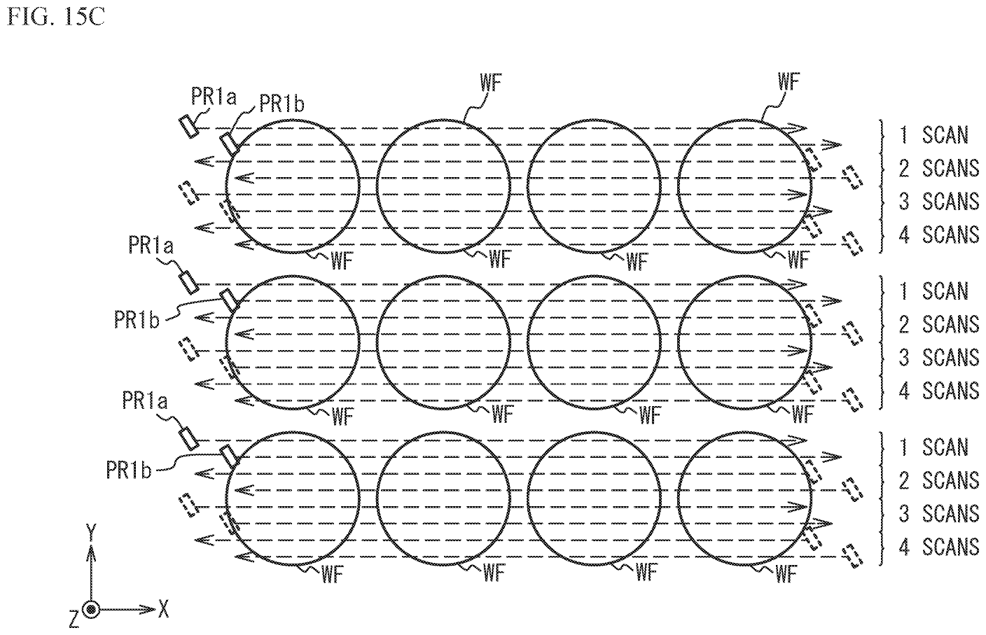

FIG. 15A is a diagram for describing a fifth arrangement example of the projection regions of the projection modules 200, and FIG. 15B is a diagram for describing the arrangement of the first projection modules 200a and the second projection modules 200b.

In the fifth arrangement example illustrated in FIG. 15A, as in the fourth arrangement example, the first projection modules 200a and the second projection modules 200b corresponding to the first projection modules 200a, respectively, are provided as the projection modules 200.

As illustrated in FIG. 15A, the interval between the adjacent projection regions PR1a in the Y-axis direction among the projection regions PR1a of the first projection modules 200a is D1a, and the interval D1a is substantially equal to the interval L1 at which the wafers WF are arranged in the Y-axis direction. The arrangement of the projection regions PR1a illustrated in FIG. 15A can be achieved by, for example, arranging the first projection modules 200a at intervals D1a substantially equal to the interval L1 in the Y-axis direction.

Each of the second projection modules 200b projects the wiring pattern onto the same wafer WF as the wafer WF onto which the corresponding first projection module 200a projects the wiring pattern, substantially simultaneously with the corresponding first projection module 200a. The projection region PR1b of each second projection module 200b is arranged at a position shifted from the projection region PR1a of the corresponding first projection module 200a by an integral division (one-eighth in FIG. 15A) of the diameter of the wafer WF in the Y-axis direction. In other words, the interval Dab between the projection regions PR1a and PR1b (see FIG. 15B) is substantially equal to an integral division of the diameter d1 of the wafer WF (Dab=d1/8 in FIG. 15B). The arrangement of the projection regions PR1b illustrated in FIG. 15A can be achieved by, for example, arranging each second projection module 200b at a position shifted from the corresponding first projection module 200a by one-eighth of the diameter d1 of the wafer WF in the Y-axis direction. In this case, when the first projection module 200a and the second projection module 200b cannot be arranged to overlap in the Y-axis direction, the first projection module 200a and the second projection module 200b are arranged to overlap in the X-axis direction as illustrated in FIG. 15B.

FIG. 15C is a diagram for describing the formation of the wiring patterns when the projection region PR1a and the projection region PR1b are arranged as illustrated in FIG. 15A. As illustrated in FIG. 15A, it is assumed that the widths of the regions R1a and R1b exposed by the first projection module 200a and the second projection module 200b, respectively, in one scan in the Y-axis direction (non-scanning direction) are W1, and the diameter d1 of the wafer WF is eight times W1. In this case, in the fifth arrangement example, the wiring patterns can be formed on all the wafers WF in four scans.

Even when the projection regions PR1a and PR1b are arranged as in the fifth arrangement example, the wiring patterns can be formed on all the wafers WF in a shorter time than in the case of the first arrangement example, as in the fourth arrangement example.

(Sixth Arrangement Example)

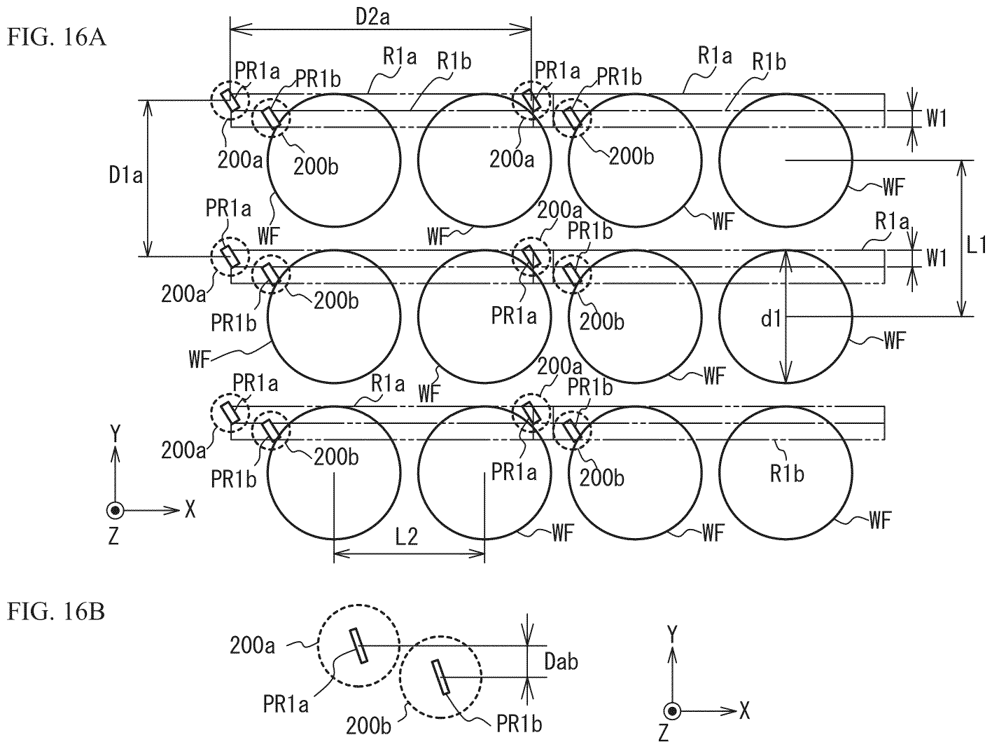

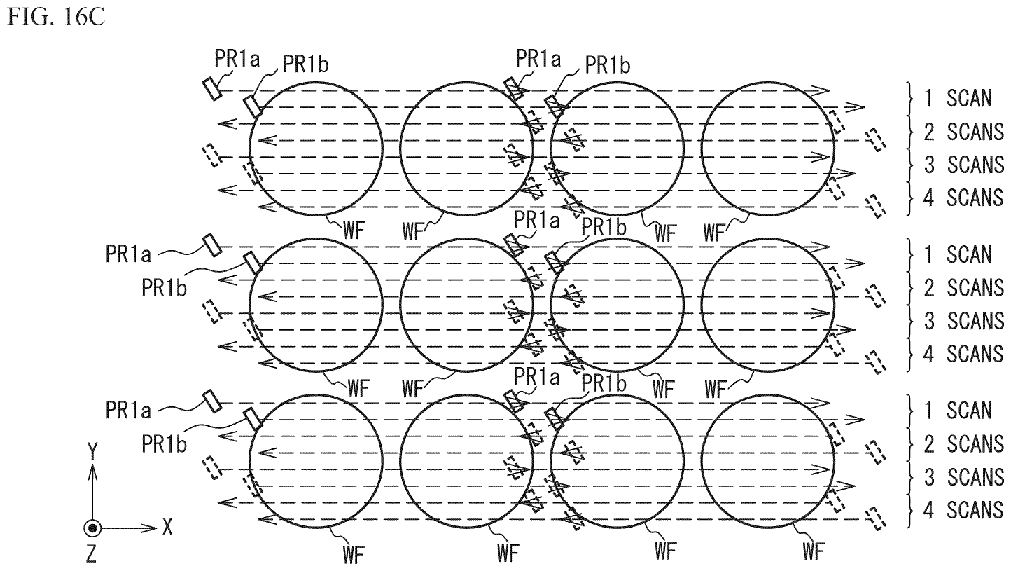

FIG. 16A illustrates a sixth arrangement example of the projection regions of the projection modules 200, and FIG. 16B is a diagram for describing the arrangement of the first projection module 200a and the second projection module 200b.

In the sixth arrangement example illustrated in FIG. 16B, a plurality of first projection modules 200a and a plurality of second projection modules 200b are provided not only in the Y-axis direction but also in the X-axis direction. That is, the first projection modules 200a are provided in a matrix of 2 columns×3 rows, and the second projection modules 200b are provided in a matrix of 2 columns×3 rows.

As illustrated in FIG. 16A, the projection regions PR1a of the first projection modules 200a are arranged so that the interval D1a between the projection regions PR1a adjacent to each other in the Y-axis direction is the same as the interval L1 at which the wafers WF are arranged. The projection regions PR1a are arranged so that the interval D2a between the projection regions PR1a adjacent to each other in the X-axis direction is two times the interval L2. The arrangement of the projection regions PR1a illustrated in FIG. 16A can be achieved by arranging the second projection modules 200a at intervals D1a substantially equal to the interval L1 in the Y-axis direction and at intervals D2a substantially equal to the interval L2 in the X-axis direction.

The projection region PR1b of each second projection module 200b is arranged at a position shifted from the projection region PR1a of the corresponding first projection module 200a by an integral division of the diameter d1 of the wafer WF in the Y-axis direction. In the example of FIG. 16A, the projection region PR1b is arranged at a position shifted from the projection region PR1a of the corresponding first projection module 200a by substantially d1/8. The arrangement of the projection regions PR1b illustrated in FIG. 16A can be achieved by, for example, arranging each second projection module 200b at a position shifted from the corresponding first projection module 200a by one-eighth of the diameter d1 of the wafer WF in the Y-axis direction, as in the case of the fifth arrangement example. In this case, when the first projection module 200a and the second projection module 200b cannot be arranged to overlap in the Y-axis direction, the first projection module 200a and the second projection module 200b are arranged to overlap in the X-axis direction as illustrated in FIG. 16B.

FIG. 16C is a diagram for describing formation of the wiring patterns when the projection regions PR1a and the projection regions PR1b are arranged as in FIG. 16A. As illustrated in FIG. 16A, it is assumed that the widths in the Y-axis direction (non-scanning direction) of the regions R1a and R1b exposed by the first projection module 200a and the second projection module 200b, respectively, in one scan are W1, and the diameter d1 of the wafer WF is substantially equal to eight times W1. In this case, the wiring patterns can be formed on all the wafers WF in four scans.

In the sixth arrangement example, since the first projection modules 200a and the second projection modules 200b are arranged also in the X-axis direction, the scanning distance in one scan is shorter than that in the fifth arrangement example. Therefore, the wiring patterns can be formed on all the wafers WF in a shorter time than in the fifth arrangement example illustrated in FIG. 15A.

As described above in detail, the exposure apparatus EX of the first embodiment includes the substrate stage 30, the DMDs 204 that form the wiring patterns each connecting the semiconductor chips (C1, C2) included in each of sets of the semiconductor chips arranged on each wafer WF of the wafers WF placed on the substrate stage 30, and the projection modules 200 or 200a that project the wiring patterns formed by the DMDs 204 onto the wafers WF, and the projection modules 200 or 200a project the respective wiring patterns onto different wafers WF substantially simultaneously. This reduces the time required to form wiring patterns compared to the case where wiring patterns are formed by a single projection module.

In the above-described fourth to sixth arrangement examples, the second projection modules 200b corresponding to the first projection modules 200a are further provided, and each of the second projection modules 200b projects the wiring pattern on the same wafer WF as the wafer WF on which the corresponding first projection module 200a projects the wiring pattern, substantially simultaneously with the corresponding first projection module 200a. This reduces the time required to form the wiring patterns compared to the case where only multiple projection modules 200 or multiple first projection modules 200a are provided.

In the first embodiment, the wafers WF are arranged at intervals L1 in the non-scanning direction (Y-axis direction) orthogonal to the scanning direction (X-axis direction) in which the substrate stage 30 is scanned, and in the first to third arrangement examples, the interval D2 between the projection regions PR1 adjacent to each other in the non-scanning direction among the projection regions PR1 of the projection modules 200 or 200a is substantially equal to an integral multiple (1 time in the first to third arrangement examples) of the interval L1. In the fourth to sixth arrangement examples, the interval D1a between the projection regions PR1a adjacent to each other in the non-scanning direction among the projection regions PR1a of the first projection modules 200a is substantially equal to an integral multiple (1 time in the fourth to sixth arrangement examples) of the interval L1. This reduces the time required to form wiring patterns compared to the case where wiring patterns are formed by a single projection module 200.

In the first embodiment, the wafers WF are arranged at intervals L2 in the scanning direction (X-axis direction) in which the substrate stage 30 is scanned, and in the second to fourth arrangement examples, the interval D2 between the projection regions PR1 of the projection modules 200 in the scanning direction is substantially equal to an integral multiple (two times in the second arrangement example, and one time in the fourth arrangement example) of the interval L2. This makes it possible to shorten the scanning distance of the substrate stage 30 as compared with the case where the projection modules 200 are not arranged in the X-axis direction, and thus to further shorten the time required to form the wiring patterns. In the sixth arrangement example, the interval D2a between the projection regions PR1a in the scanning direction is substantially equal to an integral multiple (two times in the sixth arrangement example) of the interval L2. This makes it possible to shorten the scanning distance of the substrate stage 30 as compared with the case where the first projection modules 200a are not arranged in the X-axis direction, and thus to further shorten the time required to form the wiring patterns.

In the fourth to sixth arrangement examples of the first embodiment, the projection region PR1b of the second projection module 200b is arranged at a position shifted from the projection region PR1a of the corresponding first projection module 200a by an integral division of the interval L1 (one-half in the fourth arrangement example, one-eighth in the fifth and sixth arrangement examples) in the non-scanning direction. This configuration allows the wiring patterns to be efficiently formed in each wafer WF.

Further, in the first embodiment, the exposure apparatus EX includes the measurement microscopes 65 that measure the respective positions of the wafers WF, and the measurement microscopes 65 measure the positions of different wafers WF substantially simultaneously. This makes it possible to shorten the time required to measure the positions of the wafers WF compared with the case where the positions of the wafers WF are measured by one measurement microscope 65.

Further, in the first embodiment, the interval D3 between the measurement microscopes 65 adjacent to each other in the non-scanning direction is substantially equal to the interval L1 at which the wafers WF are arranged in the non-scanning direction, and the interval D4 between the measurement microscopes 65 adjacent to each other in the scanning direction is substantially equal to the interval L2 at which the wafers WF are arranged in the scanning direction. This configuration allows the measurement microscopes 65 to measure the predetermined measurement points of the wafers WF substantially simultaneously, and therefore, the position of each wafer WF can be measured efficiently.

In the first embodiment, the exposure apparatus EX includes the first measurement microscopes 61a that measure the positions of chips included in each of the sets of the semiconductor chips, and the first measurement microscopes 61a measure the positions of the chips on different wafers substantially simultaneously. Further, the exposure apparatus EX includes the second measurement microscopes 61b corresponding to the first measurement microscopes 61a, and the second measurement microscopes 61b measure regions different from the region measured by the corresponding first measurement microscope 61a, on the same wafer WF as the wafer WF measured by the corresponding first measurement microscope 61a, substantially simultaneously with the corresponding first measurement microscope 61a. This configuration reduces the time required to measure the positions of the chips compared with the case where the positions of the chips are measured by one measurement microscope.

In the first embodiment, the interval between the first measurement microscopes 61a adjacent to each other in the scanning direction among the first measurement microscopes 61a is substantially equal to the interval L1 at which the wafers WF are arranged in the scanning direction, and the interval between the first measurement microscopes 61a adjacent to each other in the non-scanning direction among the first measurement microscopes 61a is substantially equal to the interval L2 at which the wafers WF are arranged in the non-scanning direction. This configuration allows the positions of the chips to be measured efficiently.

In the first embodiment, the widths W_{MR} of the measurement region MR1a of the first measurement microscope 61a and the measurement region MR1b of the second measurement microscope 61b in the non-scanning direction are substantially equal to an integral division of the length (diameter d1) of the wafer WF in the non-scanning direction. This configuration allows the positions of the chips to be measured efficiently.

In the first embodiment, the projection region PR1b of the second projection module 200b is arranged at a position shifted from the projection region PR1a of the corresponding first projection module 200a in the non-scanning direction, but this does not intend to suggest any limitation. For example, the projection region PR1b of the second projection module 200b may be arranged at a position shifted from the projection region PR1a of the corresponding first projection module 200a in the scanning direction. In this case, the projection region PR1b of the second projection module 200b is preferably arranged at a position shifted by an integral division of the interval L2 at which the wafers WF are arranged in the X-axis direction.

This configuration allows the wiring patterns to be efficiently formed in each wafer WF.

In the first embodiment, four second measurement microscopes 61b are arranged for one first measurement microscope 61a, but this does not intend to suggest any limitation, and the number of the second measurement microscopes 61b provided with respect to one first measurement microscope 61a may be one to three, or five or more. The second measurement microscope 61b may be omitted.

### Variation

The data generation device 300 may generate drive data that defines the driving amount of the DMD 204 and the driving amount of the lens actuator. That is, the DMD 204 may generate the wiring pattern using the design value data, and the wiring pattern to be formed on the wafer WF may be changed by changing the driving amount of the DMD 204 and the driving amount of the lens actuator to change the position of the projected image of the wiring pattern projected onto the wafer WF. The shape of the wiring pattern may be changed by optically correcting the image of the wiring pattern.

In the first embodiment and the variation thereof, the measurement microscope 61, the first measurement microscope 61a, and the second measurement microscope 61b may be movable in the Y-axis direction. This configuration allows the positions of the chips to be measured simultaneously even when the sizes of the chips are different or even when the intervals of the sets of the chips are different.

Further, in the first embodiment and the variation thereof, the projection modules 200, 200a, and 200b may be movable in the Y-axis direction. This makes it possible to cope with large placement errors that cannot be corrected by shifting or rotating the optical system or the DMD 204.

In the above embodiment, the positions of the projection regions PR1, PR1a, and PR1b are adjusted by adjusting the physical positions of the projection modules 200, 200a, and 200b, but this does not intend to suggest any limitation. For example, the positions of the projection regions PR1, PR1a, and PR1b may be optically adjusted.

### Second Embodiment

Since the step of bonding the chips to the wafer WF is performed before the formation of the wiring patterns in the exposure apparatus EX, the data generation device 300 may generate the wiring pattern data or the drive data using the measurement data acquired in the inspection step of inspecting the position of each chip with respect to the wafer WF.

FIG. 17 is a top view illustrating an outline of a wiring pattern formation system 500A in accordance with a second embodiment. The wiring pattern formation system 500A of the second embodiment includes a chip measurement station CMS for measuring the positions of chips on the wafer WF.

The chip measurement station CMS includes a plurality of measurement microscopes, and the plurality of measurement microscopes measure the positions of the semiconductor chips on different wafers WF substantially simultaneously.

(First Arrangement Example of Measurement Microscopes)

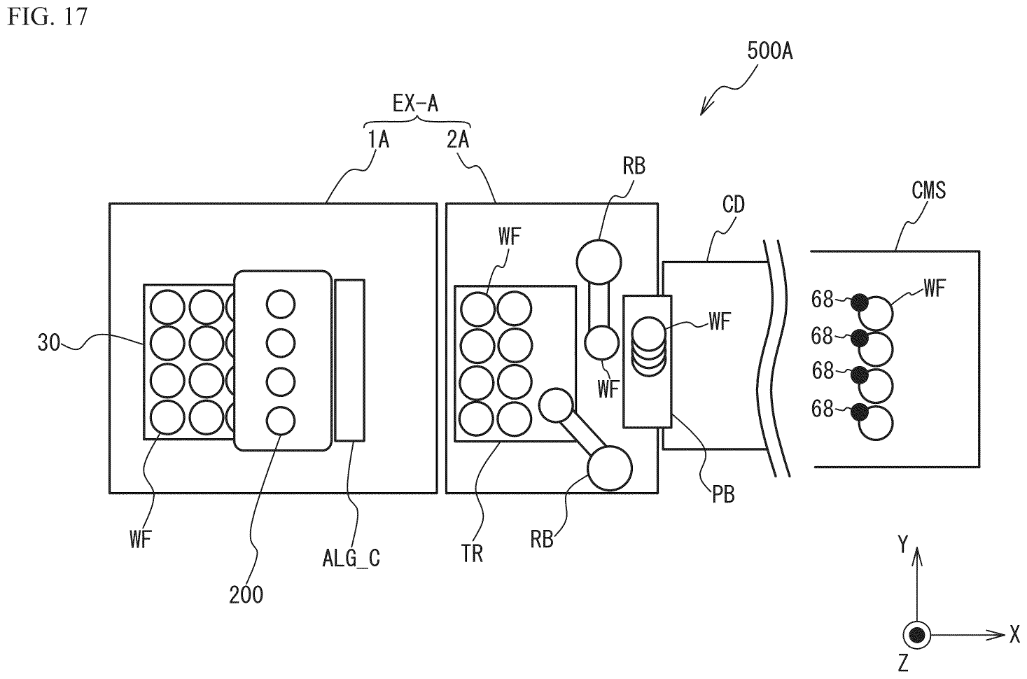

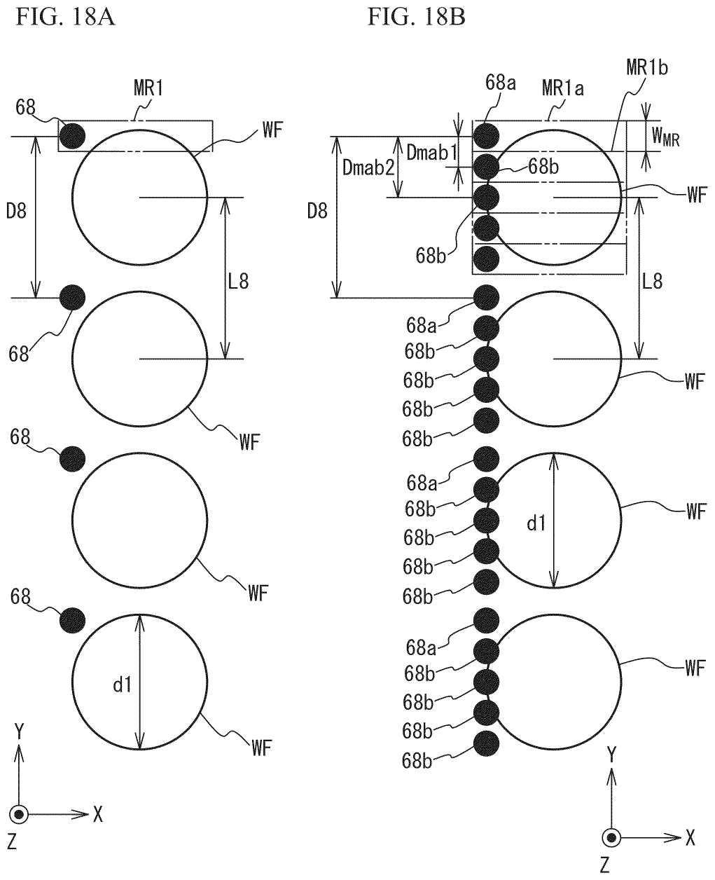

The arrangement of the measurement microscopes will be described below. FIG. 18A illustrates a first arrangement example of the measurement microscopes. In the arrangement example illustrated in FIG. 18A, a plurality of measurement microscopes 68 are provided, and the measurement microscopes 68 are arranged at intervals D8 in the Y-axis direction. In the chip measurement station CMS, when the wafers WF are arranged at intervals L8 in the Y-axis direction, by making the interval D8 substantially equal to the interval L8, the measurement microscopes 68 can measure the positions of the chips on different wafers WF substantially simultaneously.

(Second Arrangement Example of Measurement Microscopes)

FIG. 18B illustrates a second arrangement example of the measurement microscopes. In the arrangement example of FIG. 18B, a plurality of first measurement microscopes 68a and a plurality of second measurement microscopes 68b are provided as the measurement microscopes. The first measurement microscopes 68a are arranged in the Y-axis direction at intervals D8 substantially equal to the interval L8 at which the wafers WF are arranged.

The second measurement microscopes 68b are provided so as to correspond to the first measurement microscopes 68a. The second measurement microscope 68b measure regions different from the region measured by the corresponding first measurement microscope 68a on the same wafer WF as the wafer WF measured by the corresponding first measurement microscope 68a, substantially simultaneously with the corresponding first measurement microscope 68a.

In the example of FIG. 18B, four second measurement microscopes 68b are provided for one first measurement microscope 68a. When the widths of the measurement region MR1a of the first measurement microscope 68a and the measurement region MR1b of the second measurement microscope 68b in the Y-axis direction are W_{MR}, the interval between each second measurement microscope 68b and the corresponding first measurement microscope 68a is an integer multiple of W_{MR}. For example, the interval Dmab1 between the first measurement microscope 68a and the second measurement microscope 68b closest to the first measurement microscope 68a is equal to W_{MR} (1×W_{MR}), and the interval Dmab2 between the first measurement microscope 68a and the second measurement microscope 68b second closest to the first measurement microscope 68a is equal to two times W_{MR}.

By arranging the first measurement microscopes 68a and the second measurement microscopes 68b as illustrated in FIG. 18B, the time required to measure the positions of chips on one wafer WF can be reduced to 1/N of the time required to measure one wafer WF by one measurement microscope 68. N is the total number of the first measurement microscopes 68a and the second measurement microscopes 68b arranged for one wafer WF.

The number of the measurement microscopes 68, the number of the first measurement microscopes 68a, the number of the second measurement microscopes 68b, the number of wafers measured at a time in the chip measurement station CMS, and the like depend on the processing capacity of the chip measurement station CMS. Therefore, for example, when one processing device is provided for the measurement microscopes 68 and the processing capacity of the processing device is insufficient, one processing device may be provided for one measurement microscope 68, and a plurality of pairs of the measurement microscope 68 and the processing device may be provided. Alternatively, when one processing device is provided for the first measurement microscopes 68a and the second measurement microscopes 68b and the processing capacity of the processing device is insufficient, for example, one processing device may be provided for a set of the first measurement microscope 68a and the second measurement microscope 68b provided for one wafer WF, and a plurality of combinations of the set of the first measurement microscope 68a and the second measurement microscope 68b and the processing device may be provided. Further, for example, when one processing device is provided for a set of the first measurement microscope 68a and the second measurement microscope 68b provided for one wafer WF, if the processing capacity of the processing device is insufficient, the processing device may be provided for each of the first measurement microscope 68a and the second measurement microscope 68b.

Returning to FIG. 17, the measurement results of the positions of the chips are transmitted to the data generation device 300. The data generation device 300 generates wiring pattern data (or drive data) based on the measurement results of the chip positions received from the chip measurement station CMS. The wiring pattern data generated by the data generation device 300 is stored in a storage device different from the storage device in which the wiring pattern data used for the control of the exposure of the substrate currently being exposed is stored. That is, when the wiring pattern data used for the exposure control of the wafer WF currently being exposed is stored in the first storage device 310R, the data generation device 300 stores (transfers) the generated wiring pattern data in the second storage device 310L. In the case where it takes time to generate the wiring pattern data, the wiring pattern data can be generated and transferred while the resist is being applied by the coater/developer device CD, and therefore, it is effective to have two storage devices as in the present embodiment, and if necessary, the number of storage devices may be expanded to three or more.

In an exposure apparatus EX-A according to the second embodiment, a main unit 1A includes one substrate stage 30. In the second embodiment, since the chip positions are measured by the chip measurement station CMS, the alignment systems ALG_L and ALG_R can be omitted.

The wafer WF for which the measurement of the chip positions has been completed is coated with a photosensitive resist by the coater/developer device CD, and then carried into the buffer section PB. The wafers WF placed in the buffer section PB are arranged in a plurality (4 wafers×3 rows in the second embodiment) on one tray TR by the robot RB installed in a substrate exchange unit 2A, carried into the main unit 1A, and placed on the substrate holder of the substrate stage 30.

The alignment system ALG_C measures the position of each wafer WF with respect to the substrate holder, and corrects the exposure start position and the like. The configuration of the alignment system ALG_C is the same as the alignment system ALG_C of the first embodiment, and therefore, detailed description thereof will be omitted.

When the wafer WF is placed on the substrate holder, if the wafer WF rotates around the Z-axis and the positions of the chips are shifted from the positions of the wiring pattern data generated by the data generation device 300, the chips will not be connected correctly if wiring lines are formed using the wiring pattern data.

In this case, as described in the variation of the first embodiment, the data generation device 300 may correct the shape of the wiring pattern so that the chips are connected to each other by generating the drive data. For example, the data generation device 300 detects the positional shift of each chip from the position of the wiring pattern data from the position of each wafer WF measured by the alignment system ALG_C based on the position of the chip with respect to the position of each wafer WF measured by the chip measurement station CMS. The data generation device 300 generates the drive data based on the shift. Thus, even when the wafer WF is rotated around the Z-axis when the wafer WF is placed on the substrate holder, it is not necessary to rewrite the wiring pattern data, and therefore, transition to the exposure can be smoothly performed, and the wiring lines connecting the chips can be formed. The image of the wiring pattern may be optically corrected based on the positional shift of each chip. In this case, since it is not necessary to rewrite the wiring pattern data, the exposure can be smoothly performed, and the wiring lines connecting the chips can be formed.

The alignment system ALG_C can use an alignment mark of a chip for the position measurement of the wafer WF.

In the second embodiment, the chip measurement station CMS includes the measurement microscopes 68 or 68a for measuring the positions of chips included in each of the sets of chips arranged on each of the wafers WF arranged in the chip measurement station CMS. In the first arrangement example, the measurement microscopes 68 measure the positions of the chips on different wafers WF substantially simultaneously. In the second arrangement example, the first measurement microscopes 68a measure the positions of the chips on different wafers WF substantially simultaneously. This configuration reduces the time required to measure the positions of the chips compared with the case where the positions of the chips are measured by one measurement microscope 68.

Further, in the second embodiment, in the first arrangement example, the interval D8 between the measurement microscopes 68 adjacent to each other in the non-scanning direction among the measurement microscopes 68 is substantially equal to the interval L8 at which the wafers WF are arranged in the non-scanning direction. In the second arrangement example, the interval between the first measurement microscopes 68a adjacent to each other in the non-scanning direction among the first measurement microscopes 68a is substantially equal to the interval L8 at which the wafers WF are arranged in the non-scanning direction. This configuration allows the positions of the chips to be efficiently measured.

In the second arrangement example of the second embodiment, the chip measurement station CMS further includes the second measurement microscopes 68b corresponding to the first measurement microscopes 68a, and the second measurement microscopes 68b measures the respective measurement regions MR1b different from the measurement region MR1a measured by the corresponding first measurement microscope 68a on the same wafer WF as the wafer WF measured by the corresponding first measurement microscope 68a, substantially simultaneously with the corresponding first measurement microscope 68a. This configuration allows the positions of the chips to be measured in a shorter time than in the case where the positions of the chips are measured with only the multiple first measurement microscopes 68a.

In the second embodiment, the widths W_{MR} of the measurement region MR1a of the first measurement microscope 61a and the measurement region MR1b of the second measurement microscope 61b in the non-scanning direction are substantially equal to an integral division of the length (diameter d1) of the wafer WF in the non-scanning direction. This configuration allows the positions of the chips to be measured efficiently.

In the second embodiment, the measurement microscopes 68, the first measurement microscopes 68a, and the second measurement microscopes 68b may be movable in the Y-axis direction. This configuration allows the positions of the chips to be measured simultaneously even when the sizes of the chips are different or even when the intervals between the sets of the chips are different.

In the first embodiment, the measurement microscopes 61 included in the alignment systems ALG_R and ALG_L can be arranged in only one row, similarly to the measurement microscopes 68 in FIG. 18A. Further, for example, the first measurement microscopes 61a and the second measurement microscopes 61b may be arranged in only one row, similarly to the first measurement microscope 68a and the second measurement microscope 68b in FIG. 18B.

### Third Embodiment

The wafers WF may be bonded to a base substrate B, and the position of each chip with respect to the base substrate B may be measured in the chip measurement station CMS.

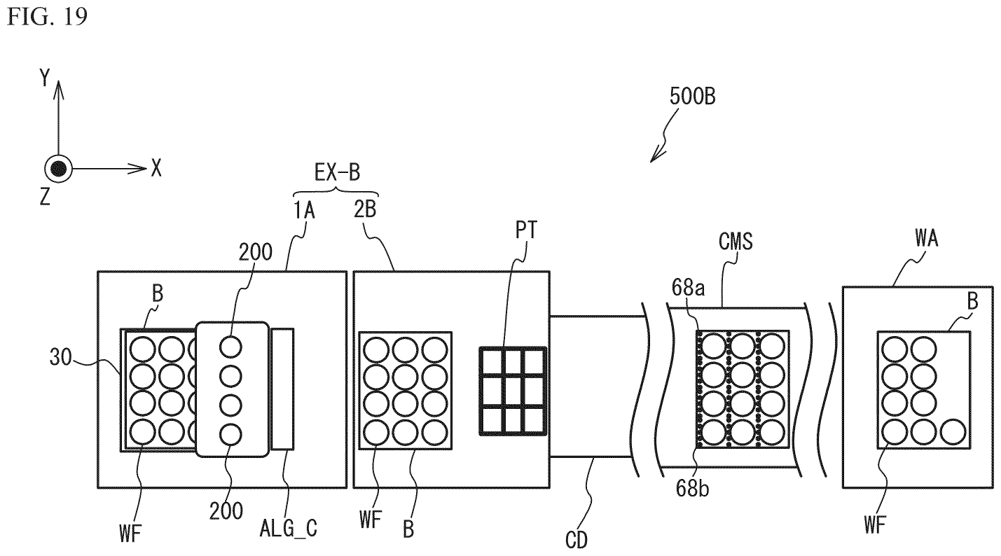

FIG. 19 is a top view illustrating an outline of a wiring pattern formation system 500B in accordance with a third embodiment. The wiring pattern formation system 500B in accordance with the third embodiment includes a wafer arrangement device WA for bonding a plurality of wafers WF, on which the chips are arranged, to the base substrate B, the chip measurement station CMS, and an exposure apparatus EX-B. The wafer arrangement device WA is for preventing the positions of the wafers WF with respect to the base substrate B from being changed.

The base substrate B on which the wafers WF are bonded by the wafer arrangement device WA is carried into the chip measurement station CMS.

The chip measurement station CMS includes the first measurement microscopes 68a and the second measurement microscopes 68b corresponding to each of the first measurement microscopes 68a. The first measurement microscopes 68a measure the positions of the chips on different wafers WF with respect to the base substrate B substantially simultaneously. The second measurement microscopes 68b measure the measurement regions MR1b different from the measurement region MR1a measured by the corresponding first measurement microscope 68a on the same wafer WF as the wafer WF measured by the corresponding first measurement microscope 68a substantially simultaneously with the corresponding first measurement microscope 68a.

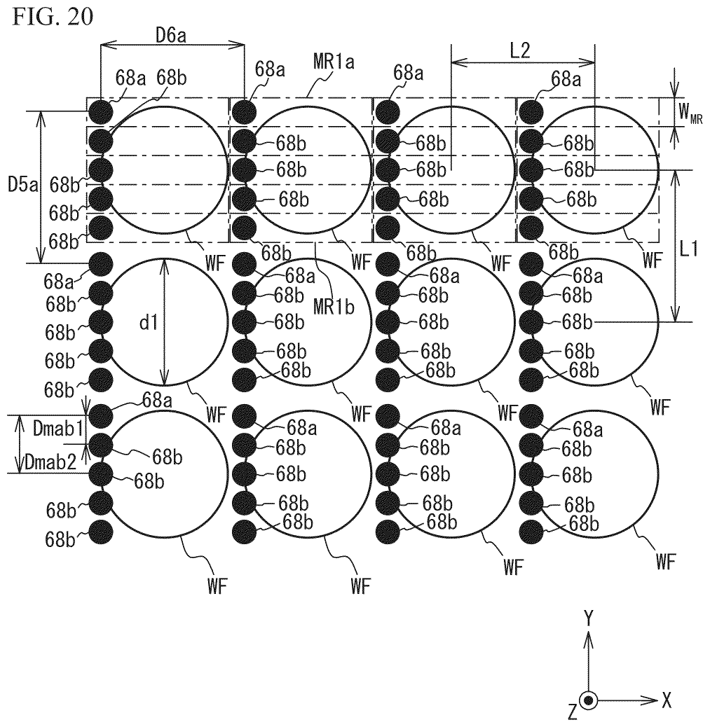

FIG. 20 illustrates an arrangement example of the first measurement microscopes 68a and the second measurement microscopes 68b. The first measurement microscopes 68a and the second measurement microscopes 68b are arranged in the same manner as the first measurement microscopes 61a and the second measurement microscopes 61b of the alignment systems ALG_L and ALG_R in the first embodiment, respectively (see FIG. 8).

Briefly, the first measurement microscopes 68a are provided in a matrix of 4 columns×3 rows to correspond to the wafers WF, respectively. The interval D5a between the first measurement microscopes 68a adjacent to each other in the Y-axis direction is substantially equal to the interval L1 at which the wafers WF are arranged in the Y-axis direction, and the interval D6a between the first measurement microscopes 68a adjacent to each other in the X-axis direction is substantially equal to the interval L2 at which the wafers WF are arranged in the X-axis direction.

Four second measurement microscopes 68b are provided for the corresponding first measurement microscope 68a. Each second measurement microscope 68b is arranged at a position shifted from the corresponding first measurement microscope 68a by an integral multiple of the width W_{MR} of the measurement region MR1a in the Y-axis direction. That is, in FIG. 20, the interval Dmab1 between the first measurement microscope 68a and the second measurement microscope 68b closest to the first measurement microscope 68a among the second measurement microscopes 68b corresponding to the first measurement microscope 68a is substantially equal to W_{MR} (1×W_{MR}), and the interval Dmab2 between the first measurement microscope 68a and the second measurement microscope 68b second closest to the first measurement microscope 68a is substantially equal to two times W_{MR}. Further, the width W_{MR} of the measurement region MR1a in the Y-axis direction is substantially equal to an integral division of the diameter d1 of the wafer WF.

Thus, the positions of the chips can be measured for all the wafers WF placed on the base substrate B in one scan, and therefore, the time required to measure the chip positions can be shortened.

The data generation device 300 generates the wiring pattern data (or drive data) based on the measurement results of the chip positions received from the chip measurement station CMS. The wiring pattern data generated by the data generation device 300 is stored in a storage device different from the storage device in which the wiring pattern data used for the exposure control of the wafers WF on the base substrate B currently being exposed is stored. That is, when the wiring pattern data used for the exposure control of the wafers WF on the base substrate B currently being exposed is stored in the first storage device 310R, the data generation device 300 stores (transfers) the generated wiring pattern data in the second storage device 310L.

The wafers WF, for which the measurement of the chip positions have been completed, are carried into the coater/developer device CD together with the base substrate B, coated with a photosensitive resist, and then carried into the port PT of a substrate exchange unit 2B. Thereafter, the wafers WF are placed on the substrate holder of the substrate stage 30 together with the base substrate B.

The subsequent processing is the same as that of the second embodiment, and thus detailed description thereof will be omitted. In the third embodiment, everything can be managed and the exposure can be performed using the position of the base substrate B on which the wafers WF are placed and fixed. For example, the alignment measurement and correction are performed on the base substrate B even in alignment. That is, since the wafers WF are placed and fixed on the base substrate B, alignment for each wafer WF/each chip is not required when the base substrate B is placed on the substrate holder of the substrate stage 30, and the alignment of only the base substrate B is performed. Although the wafer arrangement device WA bonds the wafers WF to the base substrate B, the wafers WF may be directly placed and fixed on the tray TR.

In the third embodiment, the chip measurement station CMS includes the first measurement microscopes 68a for measuring the positions of chips included in each set of semiconductor chips, and the first measurement microscopes 68a measure the positions of chips on different wafers substantially simultaneously. The chip measurement station CMS further includes the second measurement microscopes 68b corresponding to each of the first measurement microscopes 68a, and the second measurement microscopes 68b measure the measurement regions MR1b different from the measurement region MR1a measured by the corresponding first measurement microscope 68a on the same wafer WF as the wafer WF measured by the corresponding first measurement microscope 68a, substantially simultaneously with the corresponding first measurement microscope 68a. This configuration reduces the time required to measure the positions of the chips, compared with the case where the positions of the chips are measured by one measurement microscope and the case where only the first measurement microscopes 68a are provided.

In the third embodiment, the interval between the first measurement microscopes 68a adjacent to each other in the scanning direction among the first measurement microscopes 68a is substantially equal to the interval L1 at which the wafers WF are arranged in the scanning direction, and the interval between the first measurement microscopes 68a adjacent to each other in the non-scanning direction among the first measurement microscopes 68a is substantially equal to the interval L2 at which the wafers WF are arranged in the non-scanning direction. This allows the positions of the chips to be measured efficiently.

In the third embodiment, the widths W_{MR} in the non-scanning direction of the measurement region MR1a of the first measurement microscope 68a and the measurement region MR1b of the second measurement microscope 68b are substantially equal to an integral division of the length (diameter d1) of the wafer WF in the non-scanning direction. This configuration allows the positions of the chips to be measured efficiently.

In the third embodiment, the first measurement microscope 68a and the second measurement microscope 68b may be movable in the Y-axis direction. This configuration allows the positions of the chips to be measured simultaneously even when the sizes of the chips are different or even when the intervals between the sets of the chips are different.

### Variation

In the third embodiment, the wafer arrangement device WA and the chip measurement station CMS are separate apparatuses, but this does not intend to suggest any limitation. The first measurement microscope 68a and the second measurement microscope 68b may start the measurement of the chip positions from the wafer WF bonded to the base substrate B by the wafer arrangement device WA. In other words, the measurement operation is performed by the first measurement microscope 68a and the second measurement microscope 68b in parallel with the operation of bonding the wafers WF to the base substrate B. The first measurement microscope 68a and the second measurement microscope 68b may start the measurement operation after one wafer WF is bonded to the base substrate B, or may start the measurement operation after the wafers WF are bonded to the base substrate B. The first measurement microscope 68a and the second measurement microscope 68b may temporarily suspend the measurement operation at the timing when the wafer WF is placed on the base substrate B. This is to prevent the vibration generated when the wafer WF is placed on the base substrate B from affecting the measurement results of the first measurement microscope 68a and the second measurement microscope 68b.

In the third embodiment, the chip measurement station CMS can include only a plurality of the measurement microscopes 68 that measure the positions of chips on different wafers substantially simultaneously, as illustrated in FIG. 18A of the second embodiment. Further, the first measurement microscopes 68a and the second measurement microscopes 68b do not have to be arranged in a matrix, and may be arranged in only one column as illustrated in FIG. 18B of the second embodiment.

In the first to third embodiments, the projection regions PR1a of the first projection modules 200a are arranged in the Y-axis direction at intervals substantially equal to the interval L1 at which the wafers WF are arranged in the Y-axis direction, and the projection regions PR1b of the second projection modules 200b are arranged at positions shifted from the projection region PR1a of the corresponding first projection module 200a by an integral division of the diameter of the wafer WF. However, this does not intend to suggest any limitation.

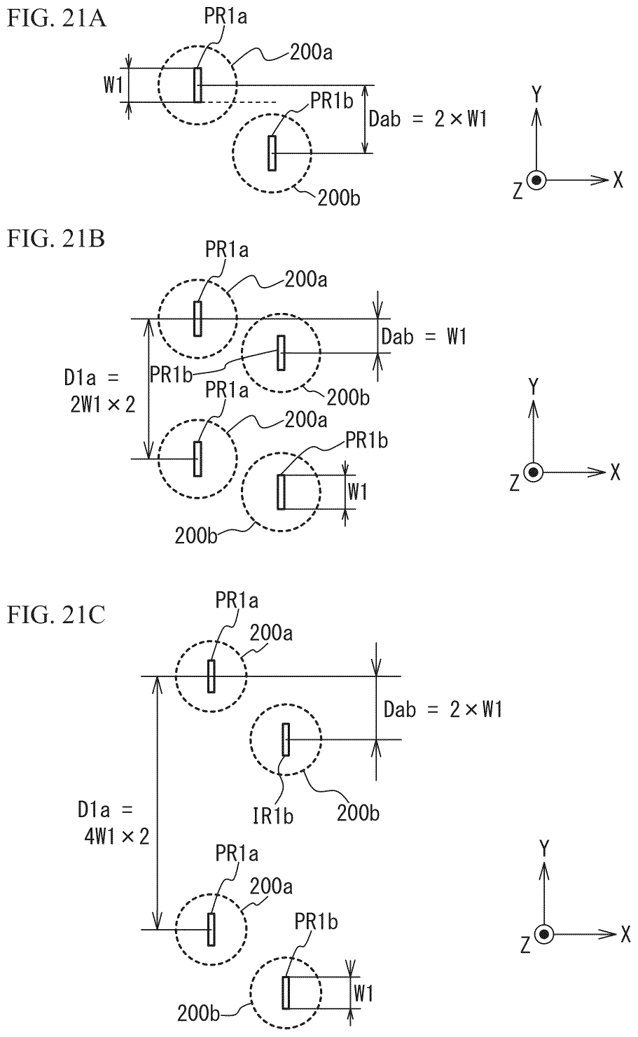

FIG. 21A to FIG. 21C are diagrams for describing the arrangement of the first projection module 200a and the second projection module 200b. For example, as illustrated in FIG. 21A, when the widths of the projection regions PR1a and PR1b in the Y-axis direction are W1, the projection region PR1b may be arranged at a position shifted from the projection region PR1a by an integral multiple of the width W1 of the projection region PR1a (Dab=2×W1 in FIG. 21A).

Alternatively, for example, as illustrated in FIG. 21B, when the widths of the projection regions PR1a and PR1b in the Y-axis direction are W1, the interval D1a between the projection regions PR1a adjacent to each other in the Y-axis direction may be set to an integral multiple of two times the width W1 (2W1) (D1a=2W1×2 in FIG. 21B), and the projection region PR1b may be arranged at a position shifted from the projection region PR1a by the width W1.

Alternatively, for example, as illustrated in FIG. 21C, when the widths of the projection regions PR1a and PR1b in the Y-axis direction are W1, the interval D1a between the projection regions PR1a adjacent to each other in the Y-axis direction may be an integral multiple of four times the width W1 (4W1) (D1a=4W1×2 in FIG. 21B), and the projection region PR1b may be arranged at a position shifted from the projection region PR1a by an integral multiple of the width W1 (Dab=W1×2 in FIG. 21B).

The number of the projection modules 200 to be arranged and the method of arranging the projection modules 200 are not limited to the first to third embodiments and the variations thereof, and may be appropriately changed so that the wiring patterns can be formed on all the wafers WF within a desired time.

In the first to third embodiments and the variations thereof, the case where a plurality of wafer-shaped substrates are placed on the substrate stage 30 has been described. However, a plurality of rectangular substrates may be placed on the substrate stage 30.

The first to third embodiments and the variations thereof are also applicable to the formation of wiring patterns that connect chips on the substrate P illustrated in FIG. 3B.

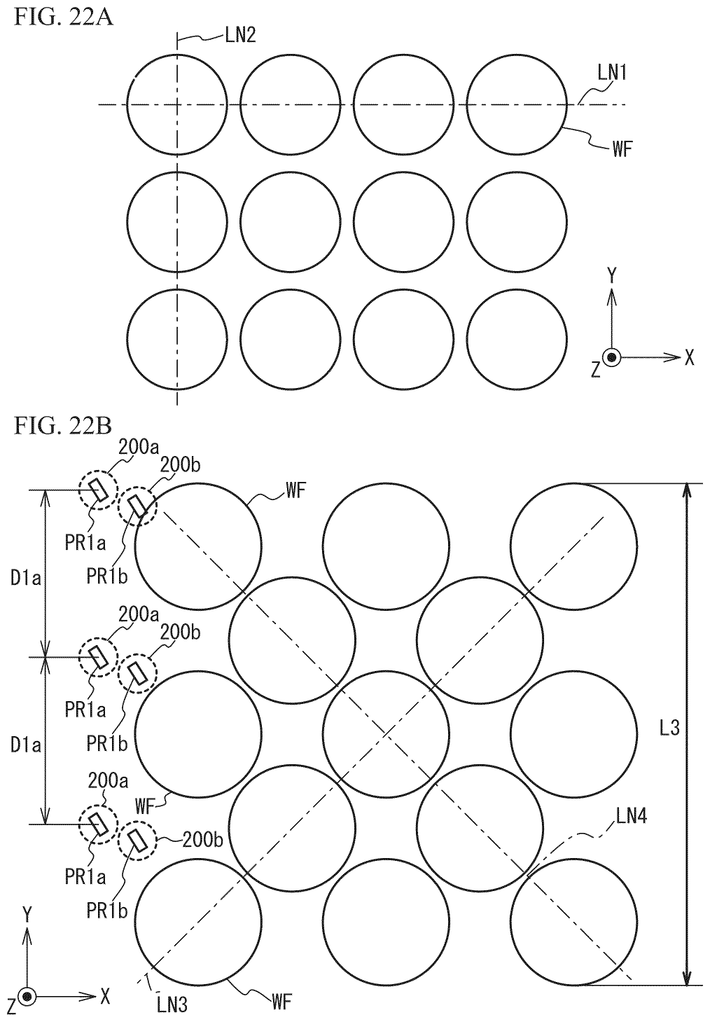

In the first to third embodiments and the variations thereof, as illustrated in FIG. 22A, the wafers WF are arranged so that lines LN1 and LN2 connecting the centers of the most adjacent wafers WF in the wafers WF are substantially parallel to the scanning direction (X-axis direction) of the substrate stage 30 and the non-scanning direction (Y-axis direction) orthogonal to the scanning direction, respectively, but this does not intend to suggest any limitation.

For example, as illustrated in FIG. 22B, the wafers WF may be arranged so that lines LN3 and LN4 connecting the centers of the most adjacent wafers WF in the wafers WF intersect the scanning direction (X-axis direction) of the substrate stage 30 or the non-scanning direction (Y-axis direction). In this case, for example, the first projection modules 200a and the second projection modules 200b may be arranged at an interval D1a substantially equal to an interval of an integral division of the maximum length L3 between the +Y end portion and the −Y end portion of the wafers WF arranged in the Y-axis direction (for example, L3/3 in FIG. 22B).

The plurality of the projection modules 200, 200a, and 200b project the wiring patterns onto a plurality of substrates P (wafers WF) based on the measurement results by the measurement microscopes 61a, 61b, 68, 68a, and 68b and the correspondence relationship between the measurement microscopes 61a, 61b, 68, 68a, and 68b and the projection modules 200, 200a, and 200b. The correspondence relationship between the measurement microscopes and the projection modules can be determined from the arrangement of the measurement microscopes and the arrangement of the projection modules, and the measurement results by the measurement microscopes can be appropriately reflected in the wiring patterns to be projected by the projection modules based on the determined correspondence relationship.

For example, when the measurement microscopes 61a arranged in 4 columns×3 rows illustrated in FIG. 8 perform measurement and the projection modules 200 arranged in every three rows illustrated in FIG. 11A project the wiring patterns, four measurement microscopes 61a arranged in the first row from the top in FIG. 8 correspond to one projection module 200 arranged in the first row from the top in FIG. 11A, four measurement microscopes 61a arranged in the second row from the top in FIG. 8 correspond to one projection module 200 arranged in the second row from the top in FIG. 11A, four measurement microscopes 61a arranged in the third row from the top in FIG. 8 correspond to one projection module 200 arranged in the third row from the top in FIG. 11A.

For example, when the measurement microscopes 61a and 61b arranged in 4 columns×15 rows illustrated in FIG. 8 perform measurement and the projection modules 200a and 200b arranged in every six rows illustrated in FIG. 14A project the wiring patterns, 12 measurement microscopes 61a and 61b arranged in the first to third rows from the top in FIG. 8 correspond to one projection module 200a arranged in the first row from the top in FIG. 14A, 12 measurement microscopes 61a and 61b arranged in the third to fifth rows from the top in FIG. 8 correspond to one projection module 200b arranged in the second row from the top in FIG. 14A, 12 measurement microscopes 61a and 61b arranged in the sixth to eighth rows from the top in FIG. 8 correspond to one projection module 200a arranged in the third row from the top in FIG. 14A, 12 measurement microscopes 61a and 61b arranged in the eighth to tenth rows in FIG. 8 correspond to one projection module 200a arranged in the fourth row from the top in FIG. 14A, 12 measurement microscopes 61a and 61b arranged in the eleventh to thirteenth rows in FIG. 8 correspond to one projection module 200a arranged in the fifth row from the top in FIGS. 14A, and 12 measurement microscopes 61a and 61b arranged in the thirteenth to fifteenth rows in FIG. 8 correspond to one projection module 200a arranged in the sixth row from the top in FIG. 14A.

The correspondence relationship between the measurement microscopes and the projection modules is appropriately determined by, for example, the arrangement of the measurement microscopes and the arrangement of the projection modules described in the first to third embodiments and the variations thereof.

Note that the disclosures of all publications, international publications, U.S. patent application publications, and U.S. patents relating to exposure apparatuses and the like cited in the above description are incorporated herein by reference.

The embodiments described above are examples of preferred embodiments of the present invention. However, the present invention is not limited thereto, and various modifications can be made without departing from the scope of the present invention.

What is claimed is:

1. An exposure apparatus comprising:
a substrate stage on which substrates are placed; and
first projection modules each including a spatial light modulator, the first projection modules projecting wiring patterns each connecting semiconductor chips arranged on each of the substrates onto the substrates;
wherein the first projection modules project the wiring patterns onto different substrates, substantially simultaneously.

2. The exposure apparatus according to claim 1, further comprising:
second projection modules,
wherein the second projection modules project the wiring patterns on different substrates, substantially simultaneously, and
wherein one of the first projection modules and one of the second projection modules project a corresponding wiring pattern of the wiring patterns on a corresponding substrate of the substrates substantially simultaneously.

3. The exposure apparatus according to claim 1,
wherein the substrates are arranged at a first interval in a non-scanning direction orthogonal to a scanning direction in which the substrate stage is scanned, and
wherein an interval between regions adjacent to each other in the non-scanning direction among first projection regions of the first projection modules is substantially equal to an integral multiple of the first interval.

4. The exposure apparatus according to claim 1,
wherein the substrates are arranged at a second interval in a scanning direction in which the substrate stage is scanned, and
wherein an interval between regions adjacent to each other in the scanning direction among first projection regions of the first projection modules is substantially equal to an integral multiple of the second interval.

5. The exposure apparatus according to claim 2, wherein in a non-scanning direction orthogonal to a scanning direction in which the substrate stage is scanned, a position of a second projection region of the one of the second projection modules is a position shifted from a first projection region of the one of the first projection modules by an integral division of a length of the substrate in the non-scanning direction.

6. The exposure apparatus according to claim 2, wherein in a scanning direction in which the substrate stage is scanned, a position of a second projection region of the one of the second projection modules is a position shifted from a first projection region of the one of the first projection modules by an integral division of a length of the substrate in the scanning direction.

7. The exposure apparatus according to claim 4, wherein each of the first projection modules projects respective wiring patterns of the wiring patterns onto two or more substrates during scanning exposure.

8. The exposure apparatus according to claim 1, further comprising:
substrate position measurement devices that measure respective positions of the substrates,
wherein the substrate position measurement devices measure the positions of different substrates substantially simultaneously.

9. The exposure apparatus according to claim 8,
wherein an interval between substrate position measurement devices adjacent to each other in a scanning direction in which the substrate stage is scanned among the substrate position measurement devices is substantially equal to a first interval at which the substrates are arranged in the scanning direction, and
wherein an interval between substrate position measurement devices adjacent to each other in a non-scanning direction orthogonal to a scanning direction in which the substrate stage is scanned among the substrate position measurement devices is substantially equal to a second interval at which the substrates are arranged in the non-scanning direction.

10. The exposure apparatus according to claim 1, further comprising:
first measurement devices that measure positions of the semiconductor chips,
wherein the first measurement devices measure the positions of the semiconductor chips on different substrates substantially simultaneously.

11. The exposure apparatus according to claim 10,
wherein an interval between the first measurement devices adjacent to each other in a scanning direction in which the substrates are scanned among the first measurement devices is substantially equal to a first interval at which the substrates are arranged in the scanning direction, and
wherein an interval between the first measurement devices adjacent to each other in a non-scanning direction orthogonal to the scanning direction among the first measurement devices is substantially equal to a second interval at which the substrates are arranged in the non-scanning direction.

12. The exposure apparatus according to claim 10, further comprising:
second measurement devices,
wherein the second measurement devices measure positions of the semiconductor chips on different substrates substantially simultaneously, and
wherein one of the first measurement devices and one of the second measurement devices measure different regions in each of the substrates, substantially simultaneously.

13. The exposure apparatus according to claim 12, wherein widths of regions measured by the first measurement devices and regions measured by the second measurement devices in a non-scanning direction orthogonal to a scanning direction in which the substrates are scanned are substantially equal to an integral division of lengths of the substrates in the non-scanning direction.

14. The exposure apparatus according to claim 1, wherein a line connecting centers of most adjacent substrates among the substrates is substantially parallel to a scanning direction of the substrate stage or a non-scanning direction orthogonal to the scanning direction.

15. The exposure apparatus according to claim 1, wherein a line connecting centers of most adjacent substrates among the substrates intersects with a scanning direction of the substrate stage or a non-scanning direction orthogonal to the scanning direction.

16. The exposure apparatus according to claim 1, wherein the first projection modules are capable of moving an exposure region in a non-scanning direction orthogonal to a scanning direction in which the substrate stage is scanned.

17. The exposure apparatus according to claim 10, wherein the first measurement devices are movable in a non-scanning direction orthogonal to a scanning direction in which the substrate stage is scanned.

18. A measurement system comprising:
first measurement devices that measure positions of semiconductor chips arranged on each of substrates placed on a substrate stage, a tray, or a base substrate,
wherein the first measurement devices measure the positions of the semiconductor chips on different substrates substantially simultaneously.

19. The measurement system according to claim 18, wherein an interval between the first measurement devices adjacent to each other in a scanning direction in which the substrates are scanned among the first measurement devices is substantially equal to a first interval at which the substrates are arranged in the scanning direction.

20. The measurement system according to claim 18, wherein an interval between the first measurement devices adjacent to each other in a non-scanning direction orthogonal to a scanning direction in which the substrates are scanned among the first measurement devices is substantially equal to an interval at which the substrates are arranged in the non-scanning direction.

21. The measurement system according to claim 18, further comprising:
second measurement devices,
wherein the second measurement devices measure positions of the semiconductor chips on different substrates substantially simultaneously, and
wherein one of the first measurement devices and one of the second measurement devices measure different regions in each of the substrates, substantially simultaneously.

22. The measurement system according to claim 21, wherein widths of regions measured by the first measurement devices and regions measured by the second measurement devices in a non-scanning direction orthogonal to a scanning direction in which the substrates are scanned is an integral division of lengths of the substrates in the non-scanning direction.

23. An exposure apparatus comprising:
a substrate stage on which one substrate is placed; and
projection modules each including a spatial light modulator, the projection modules projecting wiring patterns connecting semiconductor chips arranged on the one substrate onto the one substrate,
wherein the projection modules project respective wiring pattern of the wiring patterns, between different semiconductor chips of the semiconductor chips substantially simultaneously.

24. The exposure apparatus according to claim 23, further comprising:
measurement devices that measure positions of the semiconductor chips,
wherein the measurement devices measure positions of the different semiconductor chips substantially simultaneously.

25. An exposure apparatus comprising:
a substrate stage on which substrates are placed; and
projection modules,
wherein the projection modules project, onto the substrates, wiring patterns connecting semiconductor chips arranged on each substrate of the substrates based on measurement results obtained by measurement devices that measure the substrates and a correspondence relationship between the measurement devices and the projection modules.

26. The exposure apparatus according to claim 25,
wherein the substrate stage is scanned in a scanning direction,
wherein the projection modules are arranged in i rows (i is an integer of 2 or greater) in a non-scanning direction orthogonal to the scanning direction, with one projection module per row,
wherein the measurement devices are arranged in i rows, with j measurement devices per row, where j is an integer of 2 or greater, and
wherein the correspondence relationship is a correspondence relationship in which the j measurement devices arranged in an i-th row correspond to one projection module arranged in the i-th row.

27. The exposure apparatus according to claim 25, further comprising:
a data generation device that generates pattern data corresponding to a wiring pattern of each of the substrates,
wherein each of the projection modules includes a spatial light modulator that generates a wiring pattern for each of the substrates based on the pattern data.

28. An exposure apparatus for forming a wiring pattern for connecting semiconductor chips provided on a substrate to each other, the exposure apparatus comprising:
a first measurement device that measures first chips provided on a first substrate;
a second measurement device that measures second chips provided on a second substrate different from the first substrate;
a substrate stage on which the first substrate and the second substrate are arranged;
a first projection system that projects a first wiring pattern for connecting the first chips to each other onto the first substrate provided on the substrate stage; and
a second projection system that projects a second wiring pattern for connecting the second chips to each other onto the second substrate provided on the substrate stage,
wherein the first projection system projects the first wiring pattern based on a measurement result by the first measurement device, and
wherein the second projection system projects the second wiring pattern based on a measurement result by the second measurement device.

29. The exposure apparatus according to claim 28, further comprising:
a data generation device that generates first pattern data corresponding to the first wiring pattern and second pattern data corresponding to the second wiring pattern,
wherein the first projection system includes a first spatial light modulator that generates the first wiring pattern based on the first pattern data,
wherein the second projection system includes a second spatial light modulator that generates the second wiring pattern based on the second pattern data, and
wherein the data generation device generates the first pattern data based on a measurement result by the first measurement device and generates the second pattern data based on a measurement result by the second measurement device.
